(19) United States
(12) Patent Application Publication
(10) Pub. No.: US 2026/0129965 A1
(43) Pub. Date: May 7, 2026

(54) SEMICONDUCTOR DEVICE WITH I/O DEVICE AT GATE MODULE

(71) Applicant: INTERNATIONAL BUSINESS MACHINES CORPORATION, ARMONK, NY (US)

(72) Inventors: Paul Charles Jamison, Averill Park, NY (US); Takashi Ando, Eastchester, NY (US); Shay Reboh, Guilderland, NY (US); Junli Wang, Slingerlands, NY (US); Debarghya Sarkar, Latham, NY (US); Abir Shadman, Albany, NY (US)

(21) Appl. No.: 18/935,378

(22) Filed: Nov. 1, 2024

(51) Int. Cl. H01L 27/092; H01L 29/06; H01L 29/417; H01L 29/423; H01L 29/66; H01L 29/775; H01L 29/786

(52) U.S. Cl. CPC H10D 84/856; H10D 30/6729; H10D 30/6735; H10D 62/121; H10D 30/014; H10D 30/43; H10D 30/6757

(57) ABSTRACT

A semiconductor device includes an input/output device including: a top transistor having a top source region and top drain region and a bottom transistor comprising a bottom source region and a bottom drain region. The top source region is located over the bottom drain region, the top drain region is located over the bottom source region, the top source region is isolated from contact with the bottom drain region, and the top drain region is connected to the bottom source region.

### BACKGROUND

### Technical Field

The present disclosure generally relates to semiconductors, and more particularly, to semiconductors with I/O device at gate module structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes an input/output device having a top transistor comprising a top source region and top drain region; and a bottom transistor comprising a bottom source region and a bottom drain region. The top source region is located over the bottom drain region, the top drain region is located over the bottom source region, the top source region is isolated from contact with the bottom drain region, and the top drain region is connected to the bottom source region.

In one embodiment, the top transistor and the bottom transistor are field-effect transistors.

In one embodiment, the top transistor and the bottom transistor are doped with a P-type dopant.

In one embodiment, the top transistor and the bottom transistor are doped with an N-type dopant.

In one embodiment, the semiconductor device includes a top set of nanosheet gates horizontally extended between the top source region and the top drain region, and a bottom set of nanosheet gates horizontally extended between the bottom source region and the bottom drain region.

In one embodiment, the top drain region and the bottom source region are configured to serially connect the top transistor to the bottom transistor.

In one embodiment, the semiconductor device includes a logic device connected to the input/output device.

According to an embodiment, a method of fabricating a semiconductor device includes forming a stacked input/output device having a top transistor by forming a top source region and top drain region, and a bottom transistor by forming a bottom source region and a bottom drain region. The top source region is located over the bottom drain region, the top drain region is located over the bottom source region, the top source region is isolated from contact with the bottom drain region, and the top drain region is connected to the bottom source region.

In one embodiment, the top transistor and the bottom transistor are field-effect transistors.

In one embodiment, the method includes doping the top transistor and the bottom transistor with a P-type dopant.

In one embodiment, the method includes doping the top transistor and the bottom transistor with an N-type dopant.

In one embodiment, the method includes forming a top set of nanosheet gates horizontally extended between the top source region and the top drain region, and forming a bottom set of nanosheet gates horizontally extended between the bottom source region and the bottom drain region.

In one embodiment, the method includes forming a serially connected top transistor and bottom transistor by connecting the top drain region and the bottom source region.

In one embodiment, the method includes forming a logic device connected to the input/output device.

According to an embodiment, a semiconductor device includes an input/output device having a top transistor comprising a top source region and top drain region and a bottom transistor comprising a bottom source region and a bottom drain region. The top transistor and the bottom transistor are doped with a same dopant.

In one embodiment, the top source region is located over the bottom drain region, the top drain region is located over the bottom source region, the top source region is isolated from contact with the bottom drain region, and the top drain region is connected to the bottom source region.

In one embodiment, the top transistor and the bottom transistor are field-effect transistors.

In one embodiment, the dopant is a P-type dopant or an N-type dopant.

In one embodiment, the semiconductor device includes a top set of nanosheet gates horizontally extended between the top source region and the top drain region, and a bottom set of nanosheet gates horizontally extended between the bottom source region and the bottom drain region.

In one embodiment, the semiconductor device includes a logic device connected to the input/output device, and the top drain region and the bottom source region are configured to serially connect the top transistor to the bottom transistor.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1D illustrate cross sections of the semiconductor device, according to some embodiments.

FIGS. 2A-2D illustrate cross-section views of a semiconductor device, after the formation of the inner spacer, in accordance with some embodiments.

FIGS. 3A-3D illustrate a semiconductor device after the formation of the spin on glass, in accordance with some embodiments

FIGS. 4A-4D illustrate a semiconductor device after the removal of portions of the spin on glass, in accordance with some embodiments.

FIGS. 5A-5D illustrate a semiconductor device after the formation of the spacer liner, in accordance with some embodiments.

FIGS. 6A-6D illustrate a semiconductor device after the partial removal of the spacer liner, in accordance with some embodiments.

FIGS. 7A-7D illustrate a semiconductor device after the stripping the spin on glass, in accordance with some embodiments.

FIGS. 8A-8D illustrate a semiconductor device after the formation of the bottom source and drain regions, in accordance with some embodiments.

FIGS. 9A-9D illustrate a semiconductor device after the formation of the liner layer, in accordance with some embodiments.

FIGS. 10A-10D illustrate a semiconductor device after the high aspect ratio process, in accordance with some embodiments.

FIGS. 11A-11D illustrate a semiconductor device after blocking the semiconductor device, in accordance with some embodiments.

FIGS. 12A-12D illustrate a semiconductor device after removal of the blocking spacer layer, in accordance with some embodiments.

FIGS. 13A-13D illustrate a semiconductor device after removal of the spacer, in accordance with some embodiments.

FIGS. 14A-14D illustrate a semiconductor device after formation of the top source and drain regions, in accordance with some embodiments.

FIGS. 15A-15D illustrate a semiconductor device after the formation of the spin on glass, in accordance with some embodiments.

FIGS. 16A-16D illustrate a semiconductor device after the removal of portions of the spin on glass, in accordance with some embodiments.

FIGS. 17A-17D illustrate a semiconductor device after the formation of the spacer liner, in accordance with some embodiments.

FIGS. 18A-18D illustrate a semiconductor device after the partial removal of the spacer liner, in accordance with some embodiments.

FIGS. 19A-19D illustrate a semiconductor device after the stripping the spin on glass, in accordance with some embodiments.

FIGS. 20A-20D illustrate a semiconductor device after the formation of the bottom source and drain regions, in accordance with some embodiments.

FIGS. 21A-21D illustrate a semiconductor device after the formation of the liner layer, in accordance with some embodiments.

FIGS. 22A-22D illustrate a semiconductor device after the high aspect ratio process, in accordance with some embodiments.

FIGS. 23A-23D illustrate a semiconductor device after blocking the semiconductor device, in accordance with some embodiments.

FIGS. 24A-24D illustrate a semiconductor device after removal of the oxide layer, in accordance with some embodiments.

FIGS. 25A-25D illustrate a semiconductor device after removal of the blocking spacer layer, in accordance with some embodiments.

FIGS. 26A-26D illustrate a semiconductor device after removal of the blocking spacer layer, in accordance with some embodiments.

FIGS. 27A-27D illustrate a semiconductor device after removal of the spacer, in accordance with some embodiments.

FIGS. 28A-28D illustrate a semiconductor device after removal of the spacer, in accordance with some embodiments.

FIGS. 29A-29D illustrate a semiconductor device after formation of the top source and drain regions, in accordance with some embodiments.

FIGS. 30A-30D illustrate a semiconductor device after formation of the top source and drain regions, in accordance with some embodiments.

FIG. 31, illustrates a semiconductor device after the formation of the spin on glass.

FIG. 32 illustrates a semiconductor device after the selective removal of the sacrificial layer, in accordance with some embodiments.

FIG. 33 illustrates a semiconductor device after the formation of the interfacial layer, in accordance with some embodiments.

FIG. 34 illustrates a semiconductor device after the formation of the sacrificial layer, in accordance with some embodiments.

FIG. 35 illustrates a semiconductor device after the removal of the sacrificial layer, in accordance with some embodiments.

FIG. 36 illustrates a semiconductor device after the formation of the additional sacrificial layer, in accordance with some embodiments.

FIG. 37 illustrates a semiconductor device after the formation of the capping layer, in accordance with some embodiments.

FIG. 38 illustrates a semiconductor device after the annealing, in accordance with some embodiments.

FIG. 39 illustrates a semiconductor device after the formation of the work function metal, in accordance with some embodiments.

FIG. 40 illustrates a semiconductor device after the formation of the dielectric layer, in accordance with some embodiments.

FIG. 41 illustrates a semiconductor device after the partial stripping of the dielectric layer, in accordance with some embodiments.

FIG. 42 illustrates a semiconductor device after the stripping the dielectric layer, in accordance with some embodiments.

FIG. 43 illustrates a semiconductor device after the formation of a W layer, in accordance with some embodiments.

FIGS. 44A-44D illustrate a semiconductor device after the formation of an interlayer dielectric.

FIGS. 45A-45D illustrate a semiconductor device after the formation of a dielectric layer, according to some embodiments.

FIGS. 46A-46D illustrate a semiconductor device after the patterning of the semiconductor device, according to some embodiments.

FIGS. 47A-47D illustrate a semiconductor device after the wet stripping, according to some embodiments.

FIGS. 48A-48D illustrate a semiconductor device after the formation of a dielectric layer to pattern a contact, according to some embodiments.

FIGS. 49A-49D illustrate a semiconductor device after the formation of additional contact, according to some embodiments.

FIGS. 50A-50D illustrate a semiconductor device after the wet stripping, according to some embodiments.

FIGS. 51A-51D illustrate a semiconductor device after the patterning of the gate contacts, according to some embodiments.

FIGS. 52A-52D illustrate a semiconductor device after the opening for the gate contacts, according to some embodiments.

FIGS. 53A-53D illustrate a semiconductor device after the wet stripping, according to some embodiments.

FIG. 54 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

Gate-all-around (GAA) structure field-effect transistors (FETs), such as nanosheet devices, offer enhanced electrostatic control over the channel compared to traditional transistor architectures such as planar FETs or FinFETs. The enhanced control can facilitate meeting the requirements of further aggressive device scaling in semiconductor technology. As devices continue to shrink to nanometer dimensions, controlling short-channel effects becomes increasingly challenging. The GAA structure addresses such needs by surrounding the channel on all sides with the gate material, effectively suppressing leakage currents and improving the subthreshold slope, which in turn allows for continued scaling of transistor dimensions while maintaining optimal performance, power efficiency, and device reliability.

Stacking an n-type FET (nFET) and a p-type FET (pFET) nanosheet device on top of one another enables even further logic scaling beyond the traditional side-by-side configuration. This vertical integration reduces the physical footprint of complementary metal-oxide-semiconductor (CMOS) logic circuits, effectively doubling the transistor density without increasing the chip area. The benefits of this approach include higher packing density, which is important for meeting the demands of modern electronic devices that require more functionality in smaller form factors. Additionally, vertically stacked devices can reduce the length of interconnections between transistors, thereby decreasing parasitic capacitance and resistance. This leads to improved circuit performance, as signals can propagate more quickly and with less energy loss.

Input/Output (I/O) devices are important for circuit design because they manage the communication between the integrated circuit and external components or systems. Therefore, developing effective technology solutions for I/O devices is essential. Traditionally, I/O devices utilize a thick gate dielectric layer, typically created by the thermal oxidation of silicon (Si). This thick oxide layer is necessary to handle the higher voltage levels associated with I/O operations, providing robust insulation to prevent gate leakage currents and ensure reliable device operation. The thermal oxide offers excellent electrical properties and durability, which are crucial for the longevity and performance of I/O devices.

However, in nanosheet FETs (NSFETs), there is insufficient room to grow a thick oxide layer without adversely affecting the logic device regions. Increasing the gate dielectric thickness in the logic areas would degrade device performance by reducing the gate's electrostatic control over the channel. This can lead to higher threshold voltages and lower drive currents, negatively impacting the speed and efficiency of the logic circuits. The thin gate dielectrics used in NSFETs are important for maintaining strong gate control in these aggressively scaled devices, so introducing a thick oxide layer uniformly is not feasible without compromising performance.

To address the above-mentioned and other considerations, disclosed are methods and systems to create serially connected, stacked I/O devices simultaneously with stacked logic devices, without degrading the gate stack quality in the logic device regions. The disclosed semiconductor device can involve selectively implemented thick gate dielectrics in the I/O device areas with thin gate dielectrics in the logic device regions. Thus, the disclosed semiconductor device can offer I/O devices that can retain their ability to handle higher voltages due to the thick oxide layer, while the logic devices continue to benefit from the superior electrostatic control provided by the thin gate dielectrics in the nanosheet structure. The disclosed method allows for the integration of high-performance I/O devices into the stacked nanosheet architecture without compromising the scaling benefits and performance of the logic devices.

The benefits of such an approach are significant: first, the disclosed method for fabricating the semiconductor device can enable the continuation of device scaling trends by increasing transistor density through vertical stacking while addressing the challenges associated with integrating I/O devices into advanced architectures. By preserving the gate stack quality in logic regions, the performance advantages of nanosheet FETs are maintained, ensuring high-speed operation and energy efficiency. Simultaneously, the I/O devices can function effectively with the necessary voltage handling capabilities. The disclosed method can further enhance the overall functionality and performance of integrated circuits, making it a valuable solution for advancing semiconductor technology in an era where device scaling and integration are increasingly important.

Accordingly, the teachings herein provide methods and systems of semiconductor device with input/output devices at the gate module. The techniques described herein may be implemented in a number of ways. Example implementations are provided below with reference to the following figures.

### Example Semiconductor Device with I/O Devices at Gate Module Structure

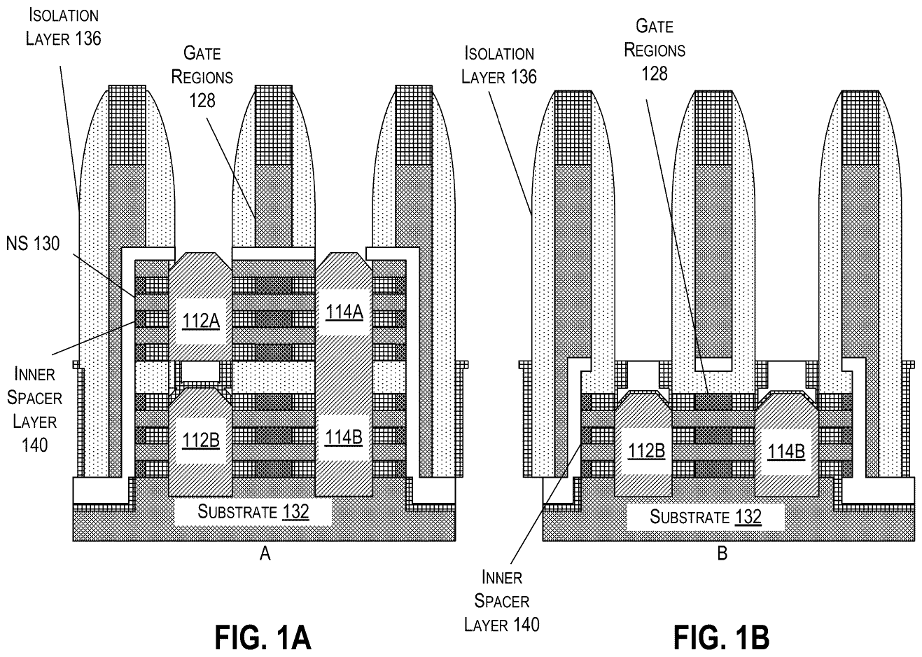

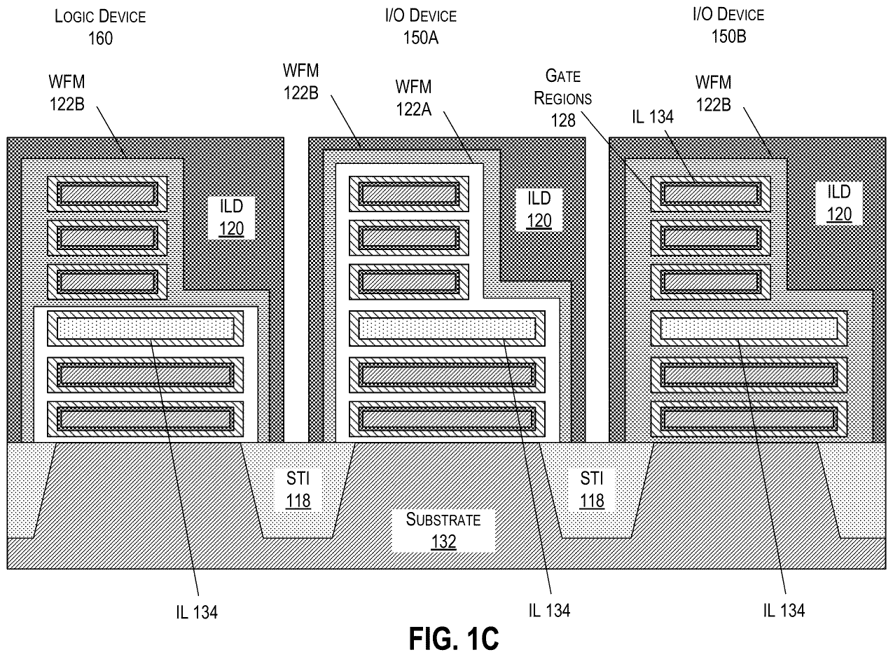

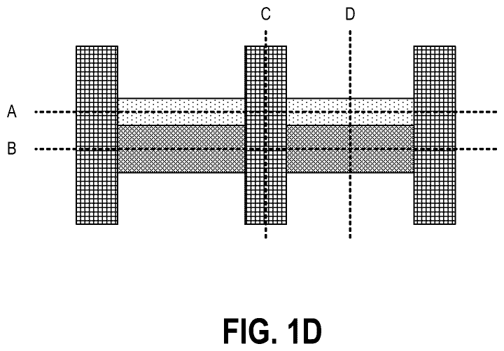

Reference now is made to FIGS. 1A-1D, which are simplified cross-section views of a semiconductor device, consistent with an illustrative embodiment. FIGS. 1A-1C illustrate various cross sections of the semiconductor device. FIG. 1D illustrates a top view of the semiconductor device. The semiconductor device includes a, a top transistor, and a bottom transistor. The top transistor can include a top source region 112A and a top drain region 112B. The bottom transistor can include a bottom source region 114A and a bottom drain region 114B. The semiconductor device can further include shallow trench isolation, STI 118, an interlayer dielectric, ILD 120, work function metals, WFM 122A and WFM 122B, gate regions 128, plurality of nanosheet gates, NS 130, a substrate 132, in interfacial layer, IL 134, an isolation layer 136, and an inner spacer 140.

The semiconductor device can include serially connected, stacked input/output (I/O) devices, e.g., I/O device 150A and I/O device 150B, without degrading the performance of stacked logic device, e.g., logic device 160. In this context, “serially connected, stacked I/O devices” can refer to I/O transistors that are vertically stacked and connected in series within a semiconductor chip. Stacking devices vertically can allow for higher integration density, reducing the physical footprint of the circuitry on the chip. The serial connection can imply that the output of one device is connected to the input of another, facilitating efficient signal flow through the stacked structure. Such a configuration can further enhance circuit functionality while conserving space, which is important for advanced electronic devices that demand more features in smaller packages.

The “stacked logic devices” can be the computational components in the chip, where both n-type and p-type transistors are used to implement logic functions. Such logic devices can be stacked vertically using nanosheet architectures, which can involve ultra-thin layers of semiconductor material acting as the transistor channels. Nanosheet devices, a form of gate-all-around (GAA) transistors, can provide enhanced electrostatic control over the channel region, allowing for further device scaling and improved performance. Maintaining the performance of the logic device 160 is important, as any degradation could negatively impact the overall speed, power efficiency, and reliability of the semiconductor device.

Gate-all-around (GAA) structure field-effect transistors (FETs), such as nanosheet devices, offer superior electrostatic control over the channel compared to traditional transistor architectures like planar FETs or FinFETs. In the GAA structure the channel is surrounded on all sides with the gate material, which effectively suppresses leakage currents and improves the subthreshold slope. Stacking an n-type FET (nFET) and a p-type FET (pFET) nanosheet device on top of one another enables even further logic scaling beyond the traditional side-by-side configuration. The vertical integration can reduce the physical footprint of the logic circuit, effectively doubling the transistor density without increasing the chip area. The benefits of this approach can include higher packing density and reducing the length of interconnections between transistors, thereby decreasing parasitic capacitance and resistance.

In some embodiments, the semiconductor device can employ a “pinched-off reliability sacrificial material”, such as oxygen-rich titanium nitride (TiN), to increase the regrowth of the IL 134 specifically in the I/O device region. The term “pinched-off” can refer to a fabrication technique where the flow or deposition of materials is restricted or controlled in certain areas to achieve desired structural characteristics. A sacrificial material can be a temporary layer introduced during the manufacturing process that serves a specific purpose and is later removed or transformed. In this case, oxygen-rich TiN is used due to its ability to influence the oxidation process during thermal treatments, promoting the growth of a thicker interfacial layer beneath the gate dielectric in the I/O regions.

Further, the IL 134 can be a thin dielectric layer that forms between the silicon channel of a transistor and the gate dielectric material, and affects factors such as threshold voltage, gate leakage current, and overall device reliability. For I/O devices, a thick IL can be utilized which allows the gate dielectric to handle higher voltages without breaking down, which in turn can enhance the operation in interfacing with external circuits that may operate at higher voltage levels than the core logic circuits.

By increasing the regrowth amount of the IL 134 in the I/O devices, 150A and 150B, the semiconductor device can ensure that the I/O transistors have the necessary dielectric thickness to operate reliably at higher voltages. The selective thickening can be achieved without affecting the thinner IL required for the logic device 160, which can rely on a thin gate dielectric to maintain electrostatic control and switching characteristics. The use of the pinched-off reliability sacrificial oxygen-rich material can allow for the IL 134 growth within the same fabrication process, enabling both device types, e.g., N-type and P-type, to coexist on the same chip without compromising performance.

In some embodiments, stacking the I/O device 150A and I/O device 150B with the NS 130 and vertically and connecting them in series can enhance the efficiency of space and can improve the performance of the I/O circuitry by reducing parasitic resistances and capacitances associated with longer interconnects.

In traditional designs, each transistor typically requires its own set of source and drain contacts, which occupy valuable space on the chip and can introduce additional complexity and resistance into the circuit. By serially connecting the stacked I/O device 150A and I/O device 150B, the number of necessary contacts can be minimized, as the drain of one transistor can serve as the source of the next in the series, which can save space and simplify the fabrication process and enhance electrical performance by reducing the number of interfaces where resistive losses can occur.

The semiconductor device can feature a vertically stacked configuration where the top source region 112A is located directly over the bottom drain region 114B. This means that within the layered structure of the semiconductor device, the source terminal of the top transistor is physically positioned above the drain terminal of the bottom transistor. Similarly, the top drain region 112B is situated over the bottom source region 114A, placing the drain terminal of the top transistor directly above the source terminal of the bottom transistor. The vertical alignment can allow for efficient use of space and enables higher device density without increasing the chip's footprint.

The top source region 112A is isolated from contact with the bottom drain region 114B. Such an electrical isolation prevents unintended current flow between the two regions, which could otherwise lead to leakage currents or interference with the semiconductor device's operation. Isolation can be achieved through the use of insulating material, e.g., the space, or by incorporating dielectric layers between the respective regions, and can ensure that the top transistor and the bottom transistor can operate independently without electrical crosstalk affecting their performance.

Conversely, the top drain region 112B is connected to the bottom source region 114A. Such an electrical connection can allow the two transistors to be serially connected, meaning the current flows from the bottom source region 114A to the bottom drain region 1114B, then continues from the top source region 112A to the top drain region 112B. This configuration can create specific circuit functionalities, such as amplifiers or logic gates, where the output of one transistor serves as the Input for another within the same device structure.

The top transistor and the bottom transistor can be field-effect transistors (FETs). Field-effect transistors are a type of transistor that uses an electric field to control the flow of current in a semiconductor channel. The FETs have three main terminals: the source, the drain, and the gate. By applying a voltage to the gate terminal, the conductivity of the channel between the source and drain can be modulated, allowing the transistor to switch between conducting and non-conducting states. FETs are fundamental components in modern electronic circuits due to their high input impedance and efficient switching characteristics.

In some embodiments, the top transistor and the bottom transistor can be doped with a P-type dopant. Doping is the process of adding impurities to a semiconductor material to change its electrical properties. P-type doping introduces elements such as boron or gallium into the semiconductor lattice, creating an abundance of “holes” or positive charge carriers. When both transistors are doped with P-type dopants, they become p-channel FETs, where the current is carried by holes moving through the channel. This configuration is useful for certain types of circuits that require p-type transistors for their operation.

Alternatively, the top transistor and the bottom transistor can be doped with an N-type dopant. N-type doping involves adding impurities like phosphorus or arsenic to the semiconductor material, introducing extra electrons as negative charge carriers. When both transistors are doped with N-type dopants, they become n-channel FETs, where electrons are the primary carriers of current. N-channel FETs typically offer higher electron mobility compared to p-channel FETs, resulting in faster switching speeds and better performance in many applications.

The semiconductor device can further include a top set of nanosheet gates that extend horizontally between the top source region 112A and the top drain region 112B. The top set of nanosheet gates are thin layers of conductive material that wrap around the channel region of the transistor, forming a gate-all-around (GAA) structure. Such a design can provide electrostatic control over the channel, reducing leakage currents and improving the transistor's switching behavior. Similarly, a bottom set of nanosheet gates extends horizontally between the bottom source region 114A and the bottom drain region 114B, offering the same benefits for the bottom transistor 110B.

By incorporating nanosheet gates in both the top transistor and the bottom transistor, the semiconductor device's overall performance is enhanced, enabling more precise control of the current flow and allowing for further scaling down of transistor dimensions. The horizontal extension of these gates ensures uniform control across the entire width of the channel, which is essential for maintaining consistency and reliability in the transistor's operation.

In some embodiments, the semiconductor device can include the logic device 160 connected to the I/O devices. Thus, in addition to the stacked transistors functioning as input/output (I/O) devices, there is an integrated logic component within the same device structure. The logic device 160 can perform computational functions, processing signals received from the I/O devices or controlling their operation based on programmed instructions. Connecting the logic device 160 to the I/O devices, I/O device 150A and I/O device 150B, can allow for seamless communication between input, processing, and output stages within the semiconductor device.

Generally, the source/drain regions, are salient components that play relevant roles in the semiconductor device's operation. In various embodiments, the source/drain regions are region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The ILD 120 can be a layer of insulating material to electrically isolate and provide mechanical support between different layers of conducting and active components. The ILD 120 can enable efficient signal transmission, reduce crosstalk, and ensure the proper functioning of the semiconductor device. In an embodiment, the ILD 120 can electrically isolate adjacent conducting layers or active components in the device. By providing insulation between different layers, the ILD 120 can prevent electrical shorts, reduce (e.g., minimize) leakage current, and ensure that signals are directed only along the desired pathways. In some embodiments, the ILD 120 can help reduce parasitic capacitance between adjacent metal interconnects or active devices and provide mechanical support to the active device's structure.

The STI 118 can electrically isolate different components by filling the trenches with an insulating material, such as silicon dioxide. The STI 118 can prevent electrical interference and crosstalk between adjacent devices, ensuring that each component operates independently without affecting its neighbors.

In various embodiments, the gate regions 128 serve as control elements that regulate the flow of current through the device. The gate regions 128 can be composed of a conductive material. The gate regions 128 can control the flow of electric current between the source and drain regions. In addition to acting as a switch, modulating the gate voltage can enable the gate regions 128 to control the current flowing through the channel region, resulting in amplified output signals.

In an embodiment, the gate regions 128 can enable the implementation of Boolean logic operations, such as AND, OR, and NOT, by controlling the flow of current based on the input voltages. In some embodiments, the gate regions 128, along with other active device components, can facilitate the miniaturization and integration of electronic circuits. The ability to control the channel region's conductivity through the gate voltage allows for compact and highly efficient circuit designs.

In some embodiments, the semiconductor device includes a set of input/output devices stacked on each other. In some embodiments, the semiconductor device includes a top transistor and a bottom transistor serially connected to each other by connecting the top drain region to the bottom source region. In some embodiments, the top transistor and the bottom transistor are doped with a same dopant.

### Example Fabrication of Semiconductor Device with I/O Devices at Gate Module

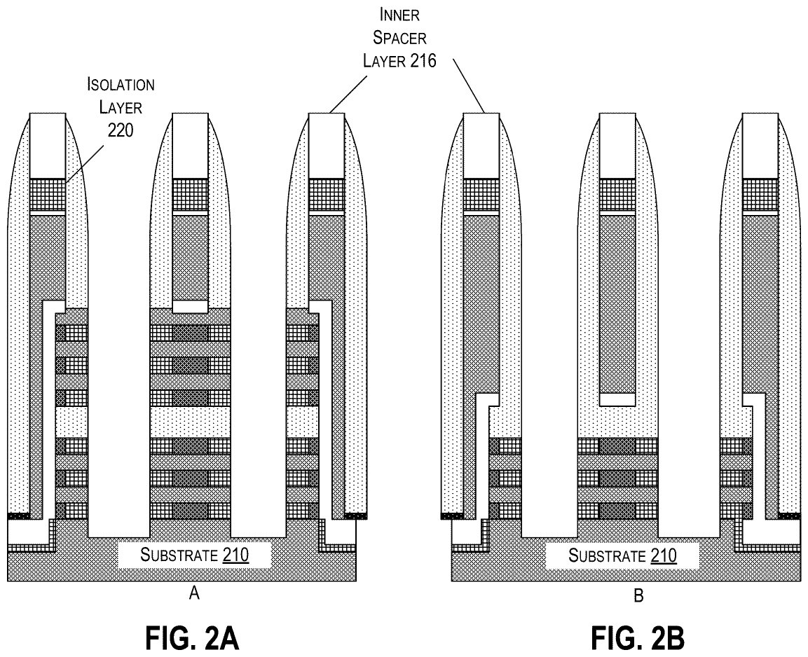

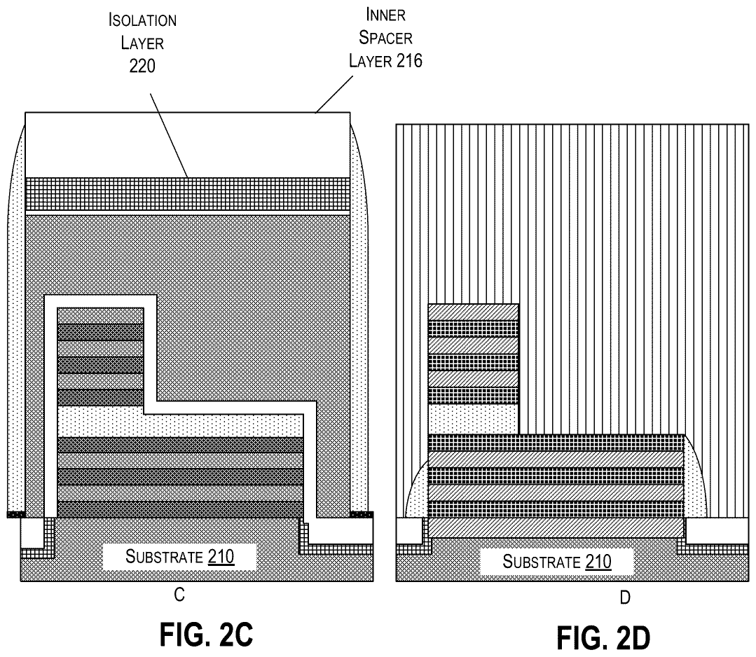

With the foregoing description of an example semiconductor device, it may be helpful to discuss an example process of manufacturing the same. To that end, FIGS. 2-14 illustrate various acts in the manufacture of a semiconductor device with the focus on the fabrication of the type B, e.g., an NFET, I/O device, consistent with illustrative embodiments.

Reference now is made to FIGS. 2A-2D, which is a simplified cross-section view of a semiconductor device, after the formation of the inner spacer, consistent with an illustrative embodiment. The semiconductor device can include a substrate 210, layers of SiGe, an inner spacer 216, and an isolation layer 220.

In the illustrative example depicted in FIGS. 2A-2D, the semiconductor device is depicted as being on silicon as the substrate 210, while it will be understood that other types as the substrate 210 may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 210 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

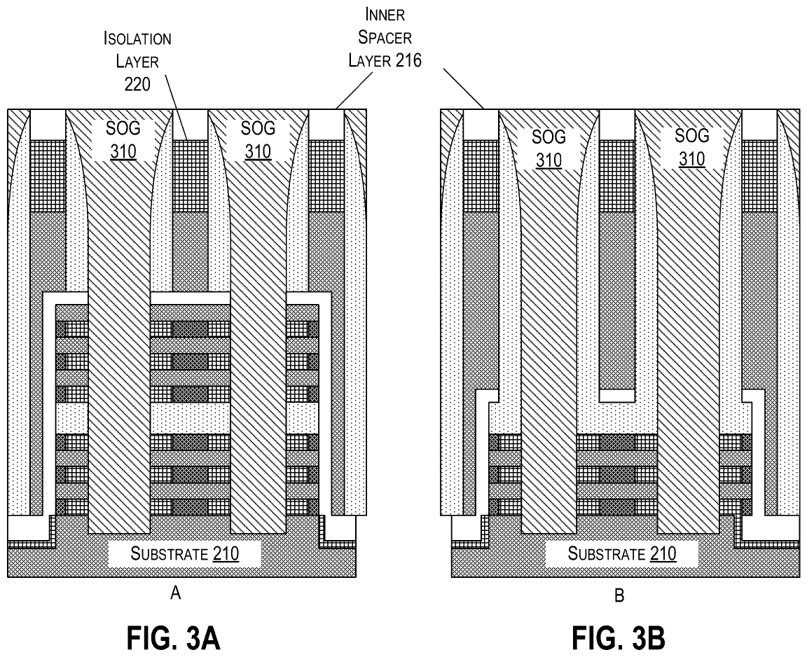

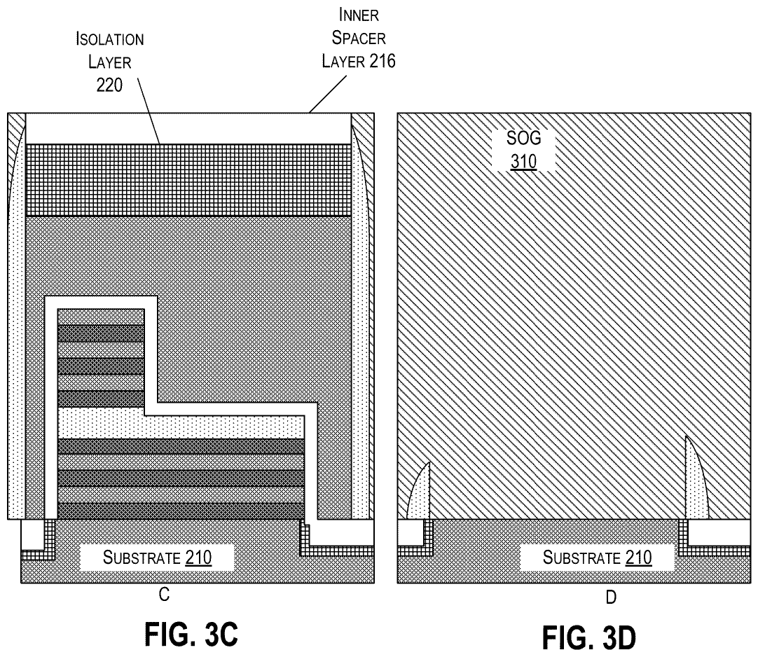

FIGS. 3A-3D illustrate a semiconductor device after the formation of the spin on glass, in accordance with some embodiments. In some embodiments, the spin on glass, SOG 310, is formed over the semiconductor device.

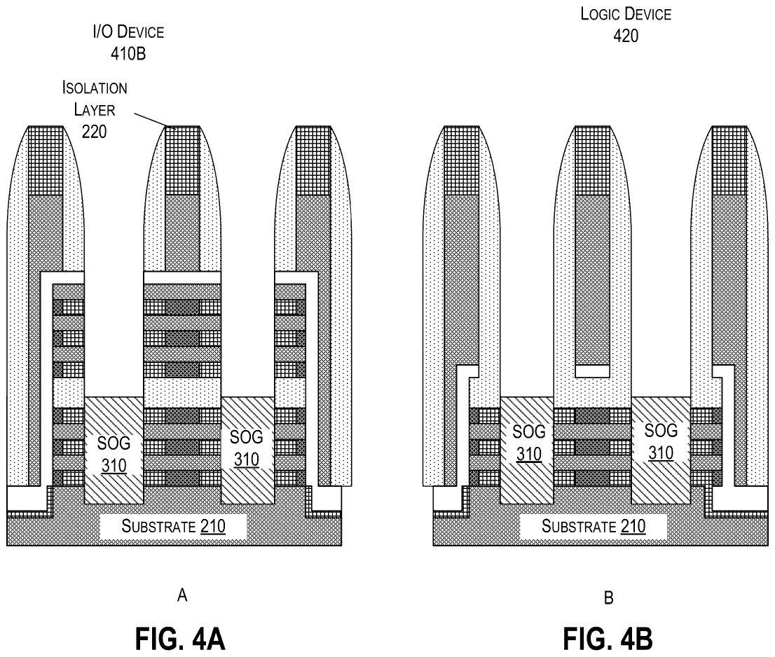

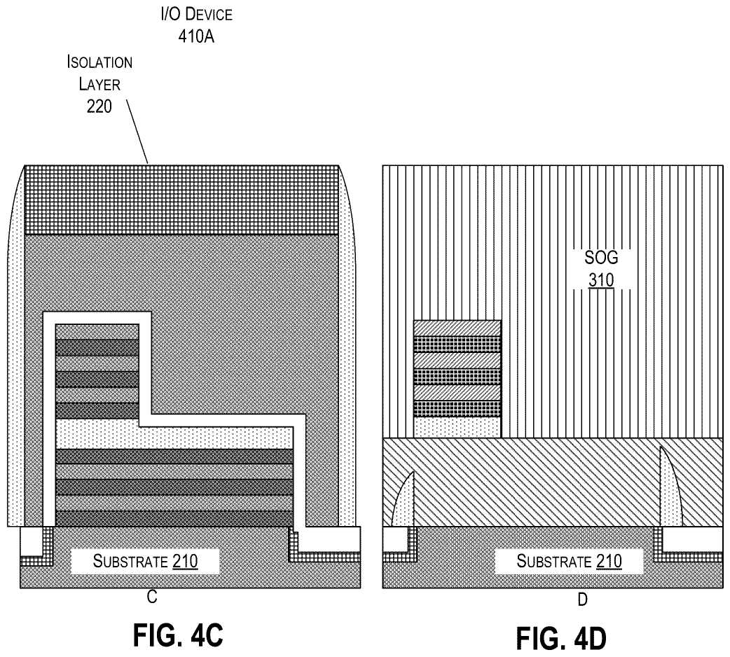

FIGS. 4A-4D illustrate a semiconductor device after the removal of portions of the spin on glass, in accordance with some embodiments. In some embodiments, portions of the SOG are removed from the semiconductor device. It should be noted that, one I/O device 410A remains blocked and portions of the SOG are removed from the other I/O device, I/O device 410B and the logic device 420.

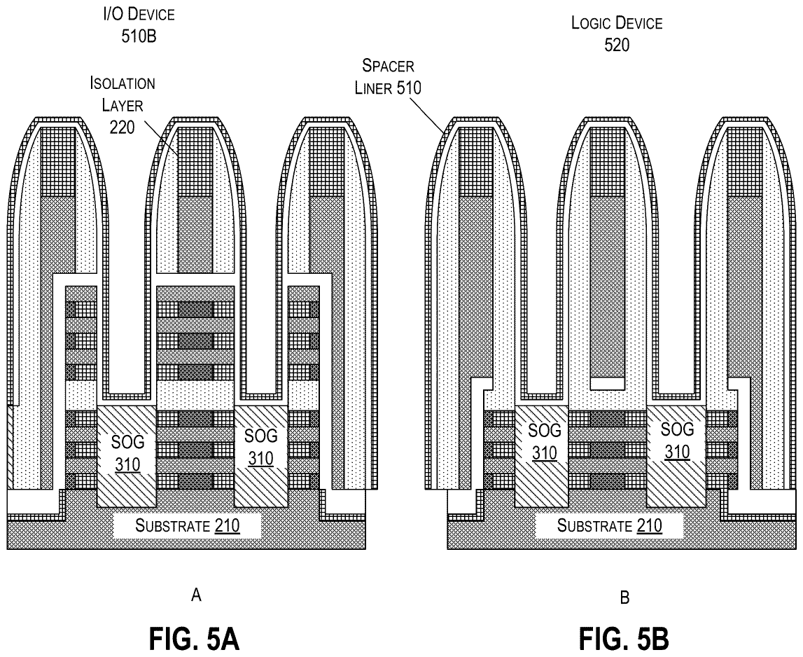

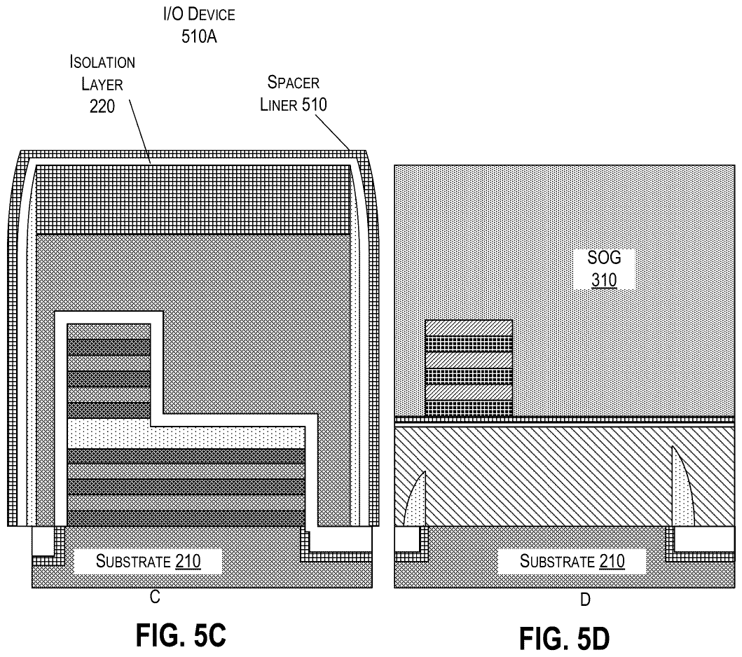

FIGS. 5A-5D illustrate a semiconductor device after the formation of the spacer liner, in accordance with some embodiments. In some embodiments, the spacer liner 510 is formed over the semiconductor device. It should be noted that, one I/O device 510A remains blocked and the spacer liner 510 is formed over the other I/O device, I/O device 510B and the logic device 520.

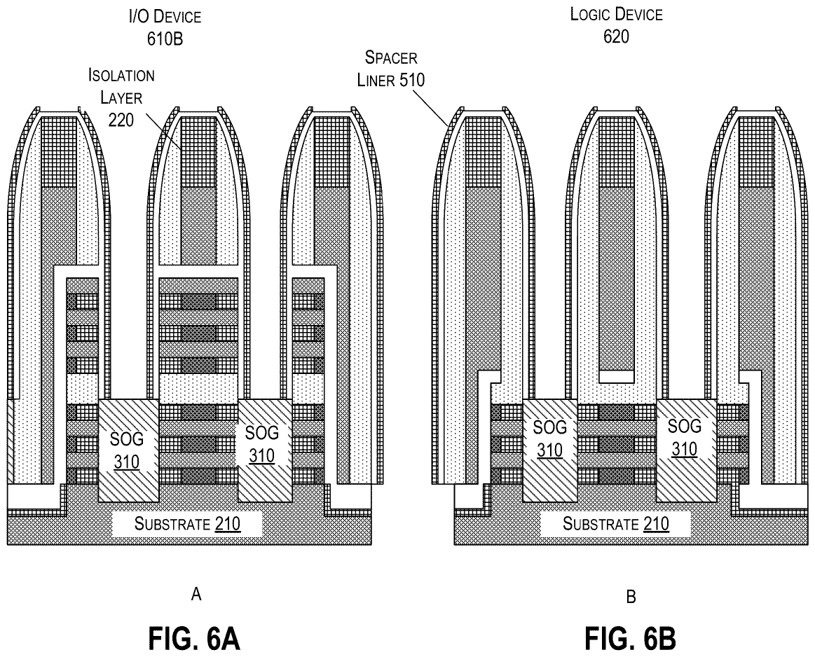

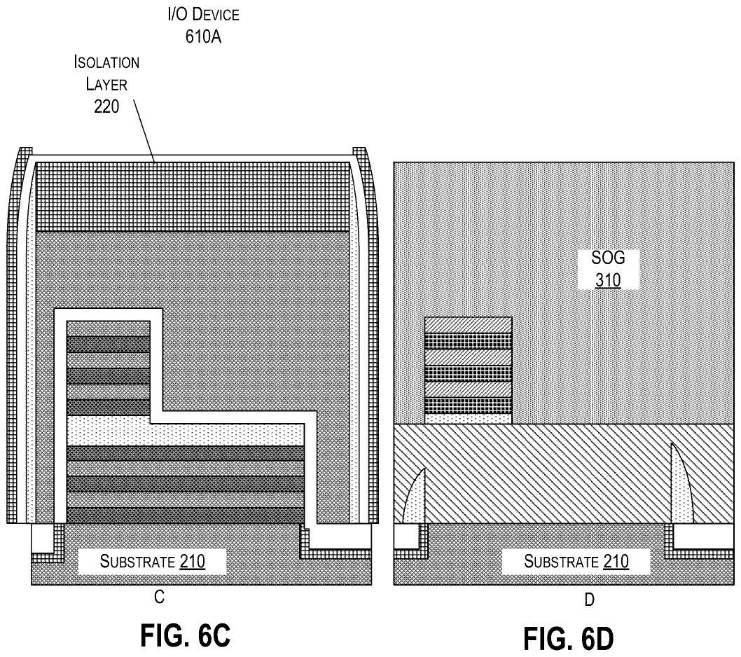

FIGS. 6A-6D illustrate a semiconductor device after the partial removal of the spacer liner, in accordance with some embodiments. In some embodiments, the spacer liner over the top surfaces of the semiconductor device are removed. It should be noted that, one I/O device 610A remains blocked and the spacer liner is removed from the top surfaces of the other I/O device, I/O device 610B and the logic device 620.

A reactive ion etching (RIE) technique can be performed to remove the spacer liner. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants.

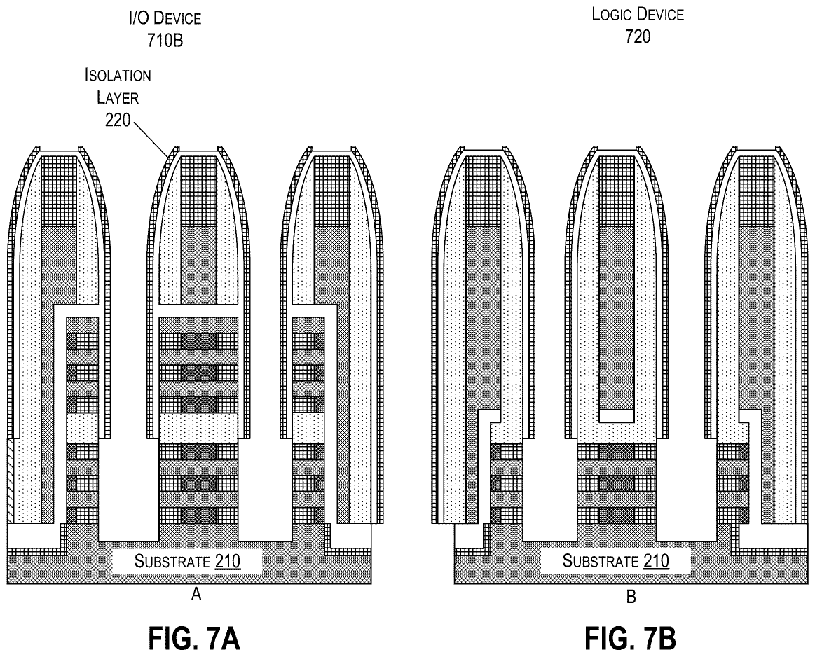

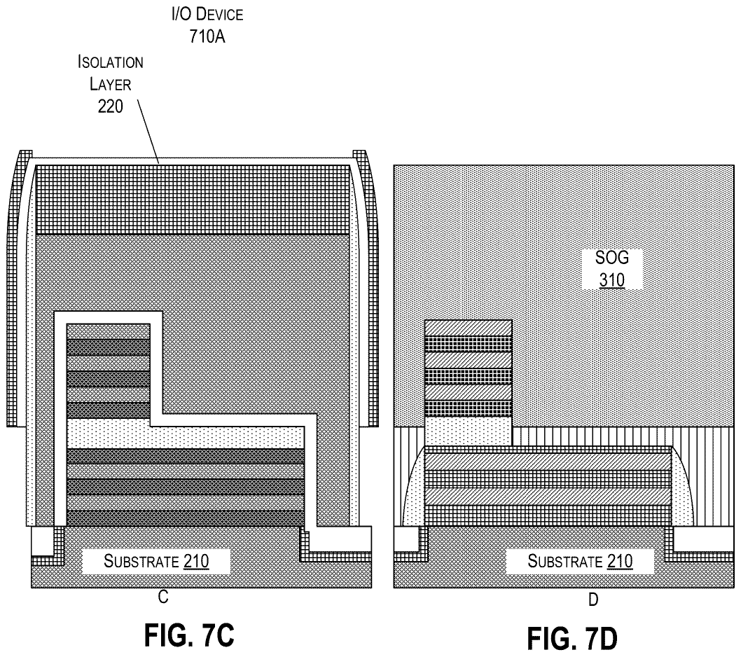

FIGS. 7A-7D illustrate a semiconductor device after the stripping the spin on glass, in accordance with some embodiments. In some embodiments, the remaining SOG are removed. It should be noted that, one I/O device 710A remains blocked and the SOG is removed from the top surfaces of the other I/O device, I/O device 710B and the logic device 720.

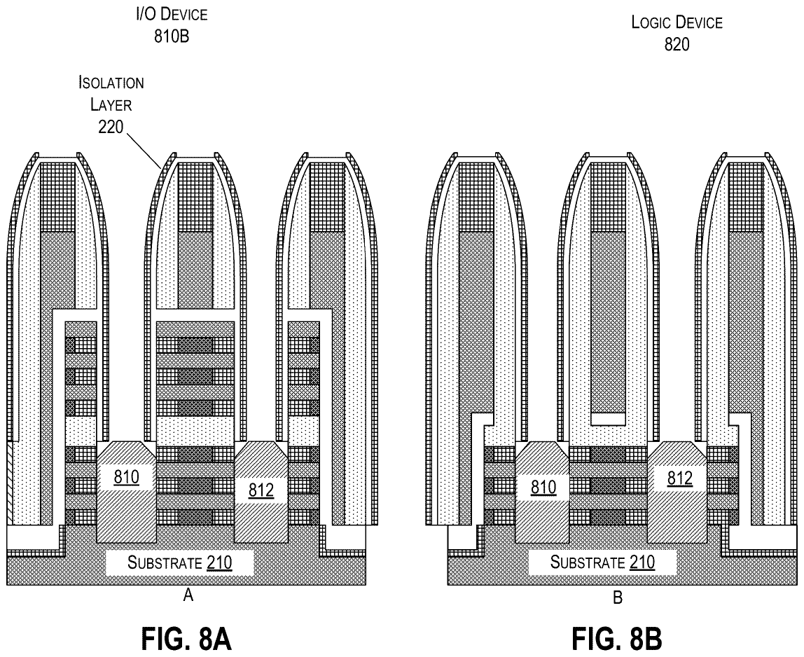

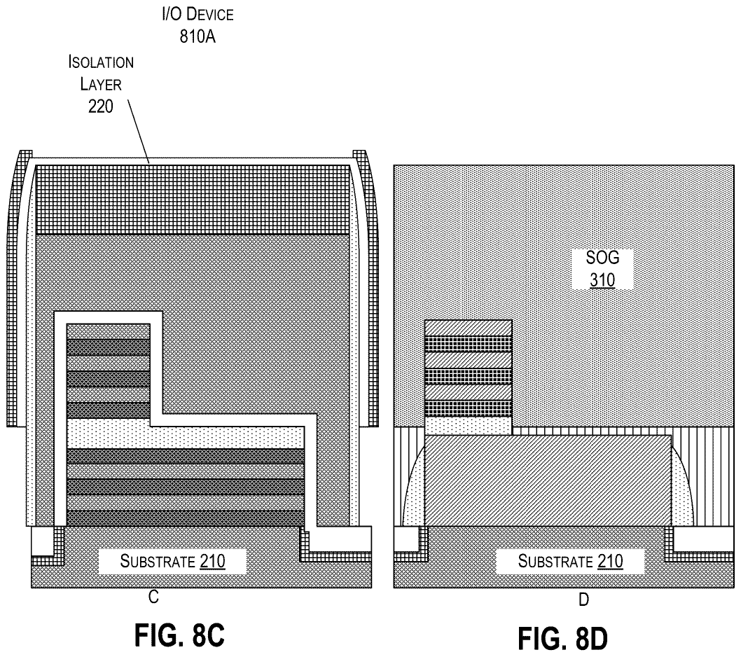

FIGS. 8A-8D illustrate a semiconductor device after the formation of the bottom source and drain regions, in accordance with some embodiments. In some embodiments, the bottom source region 810 and the bottom drain region 812 are formed. It should be noted that, one I/O device 810A remains blocked and the bottom source and drain are formed over the other I/O device, I/O device 810B and the logic device 820.

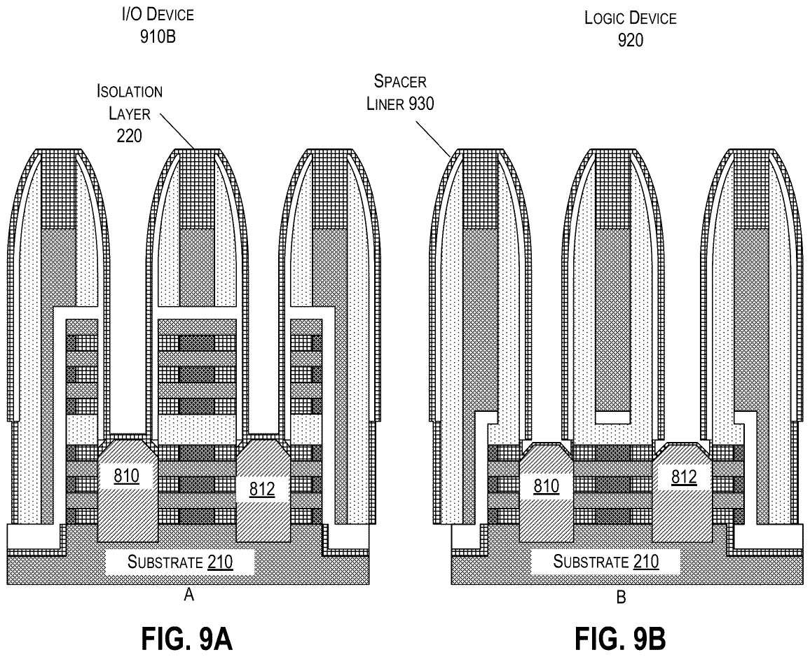

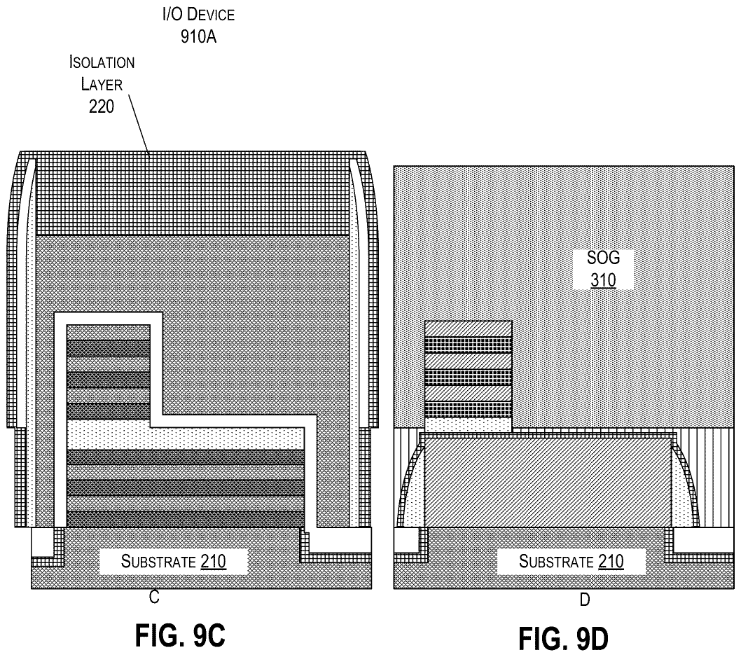

FIGS. 9A-9D illustrate a semiconductor device after the formation of the liner layer, in accordance with some embodiments. In some embodiments, the liner layer 930 is formed over the semiconductor device. It should be noted that, one I/O device 910A remains blocked and the liner layer 930 is formed over the other I/O device, I/O device 910B and the logic device 920.

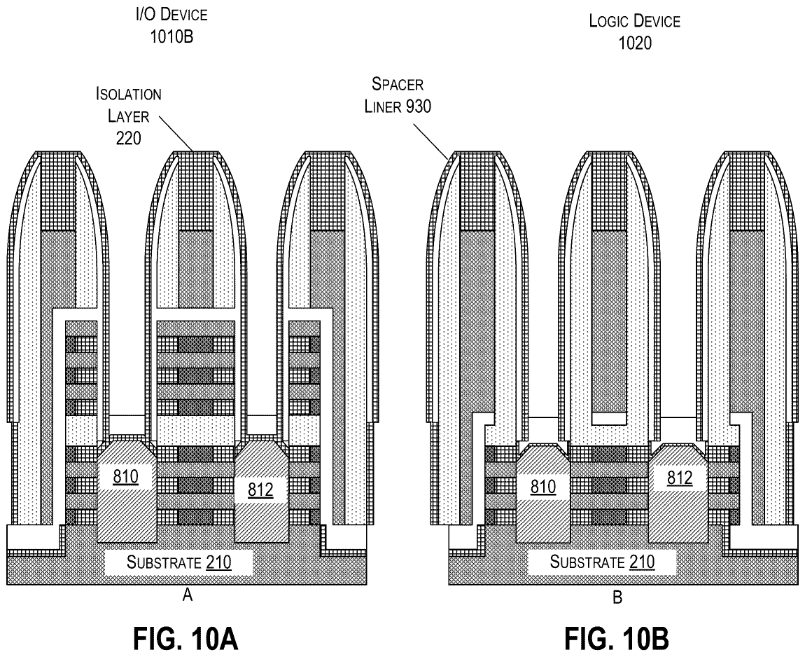

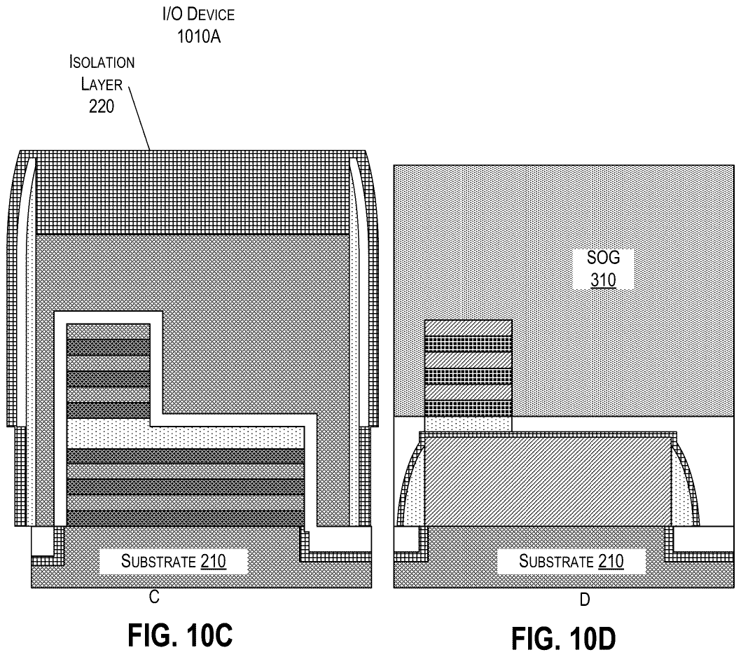

FIGS. 10A-10D illustrate a semiconductor device after the high aspect ratio process, in accordance with some embodiments. A flowable chemical vapor deposition (FCVD) and high aspect ratio process (HARP) deposition can be performed. FCVD is a specialized form of chemical vapor deposition where a flowable dielectric material, such as silicon dioxide, is deposited onto the wafer surface. In a FCVD process, the deposited film initially possesses flowable properties, allowing it to conformally fill high-aspect-ratio structures and narrow gaps without leaving voids or seams. The flowable film can penetrate deeply into intricate spaces between transistor features, which is essential as device dimensions shrink and the aspect ratios of features increase. After deposition, the film undergoes a curing process—often involving thermal annealing or ultraviolet (UV) light exposure—that solidifies it into a dense, solid dielectric layer with the desired electrical and mechanical properties. FCVD can achieve gap filling, planarization of the wafer surface, and stress reduction within the device, all of which contribute to the reliable performance of transistors.

HARP deposition can deposit dielectric materials into features with high aspect ratios. HARP utilizes a sub-atmospheric chemical vapor deposition (SACVD) process to deposit high-quality silicon oxide films. By controlling the reaction conditions—such as pressure, temperature, and gas composition—HARP enables the conformal deposition of dielectric materials into deep trenches and narrow gaps between transistor components. This method ensures that the dielectric fills the spaces uniformly, eliminating voids and seams that could compromise device reliability. It should be noted that, one I/O device 1010A remains blocked and the bottom source and drain are formed over the other I/O device, I/O device 1010B and the logic device 1020.

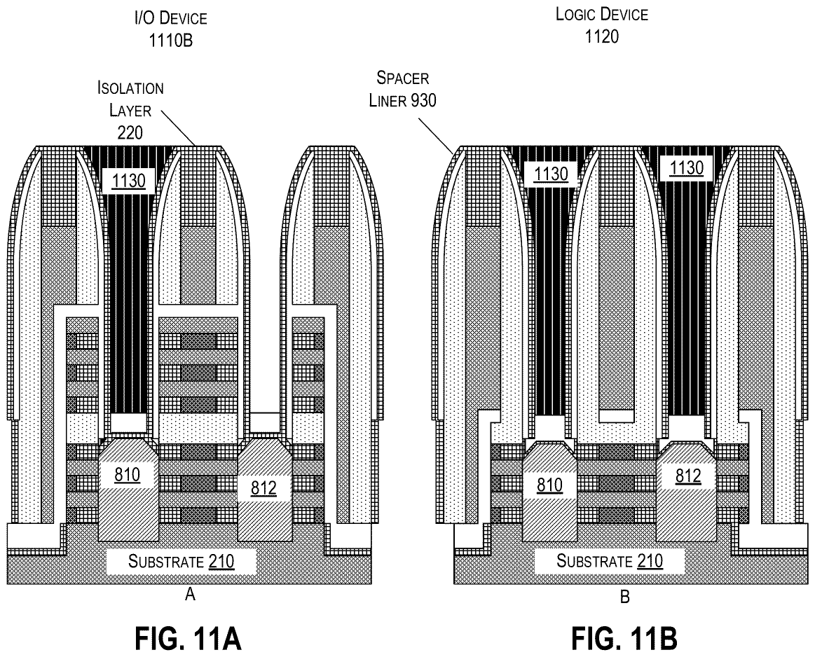

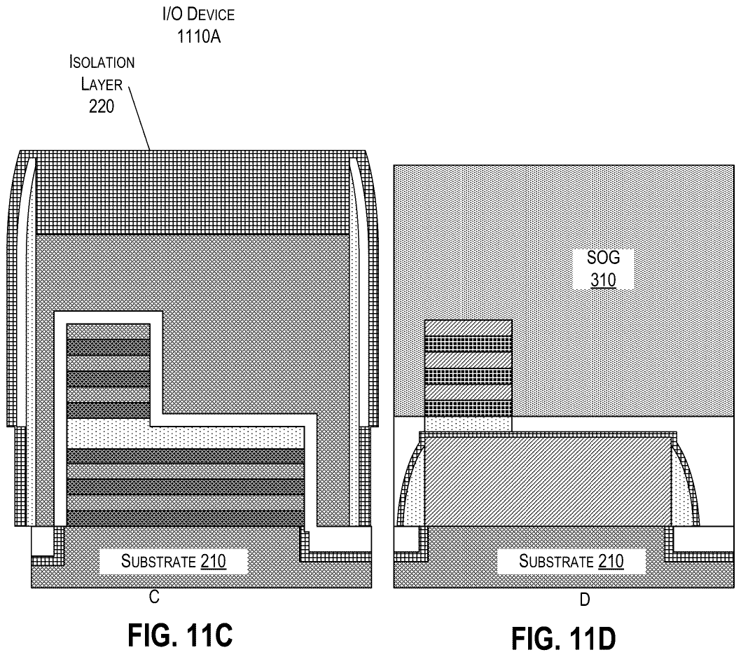

FIGS. 11A-11D illustrate a semiconductor device after blocking the semiconductor device, in accordance with some embodiments. In some embodiments, the semiconductor device, I/O device 1110A, except the drain region of the I/O device 1110B, are blocked by a suitable material such as SiN blocking spacer 1130.

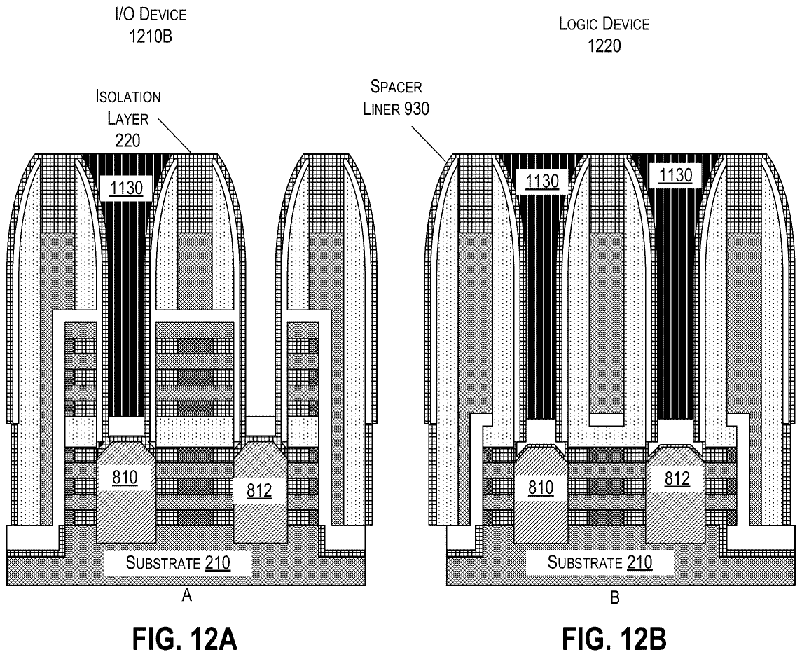

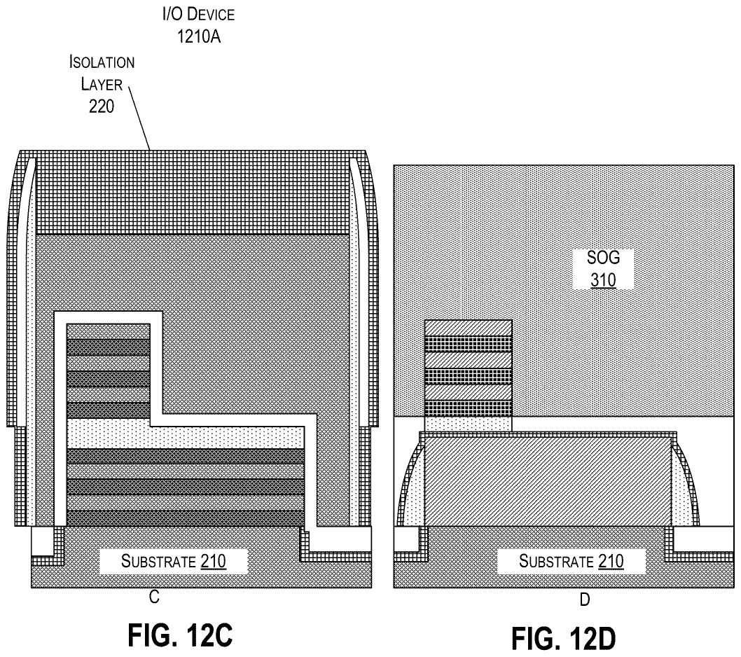

FIGS. 12A-12D illustrate a semiconductor device after removal of the oxide layer, in accordance with some embodiments. In some embodiments, the oxide layer is removed from the semiconductor device. It should be noted that, one I/O device 1210A and the logic device 1220 remain blocked and the oxide layer is removed from the other I/O device, I/O device 1210B.

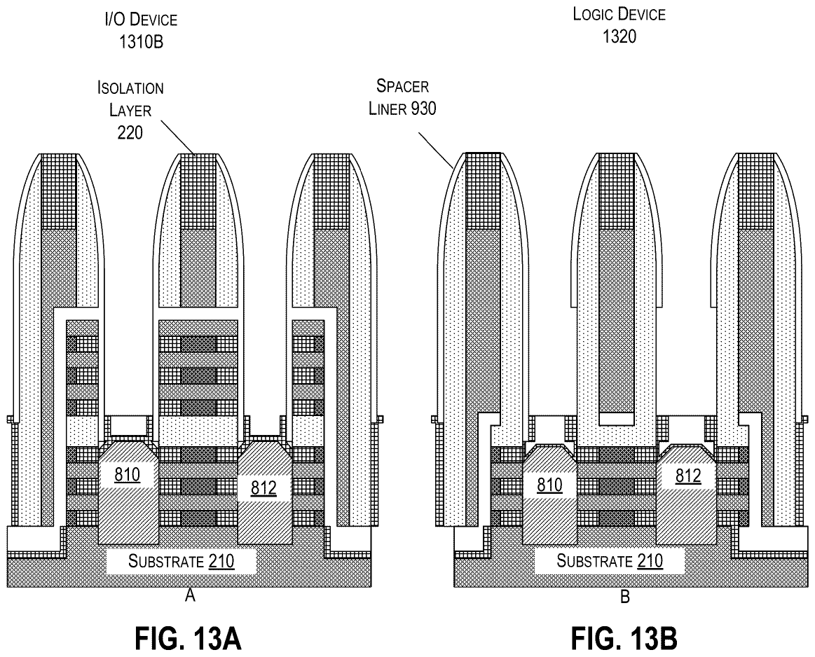

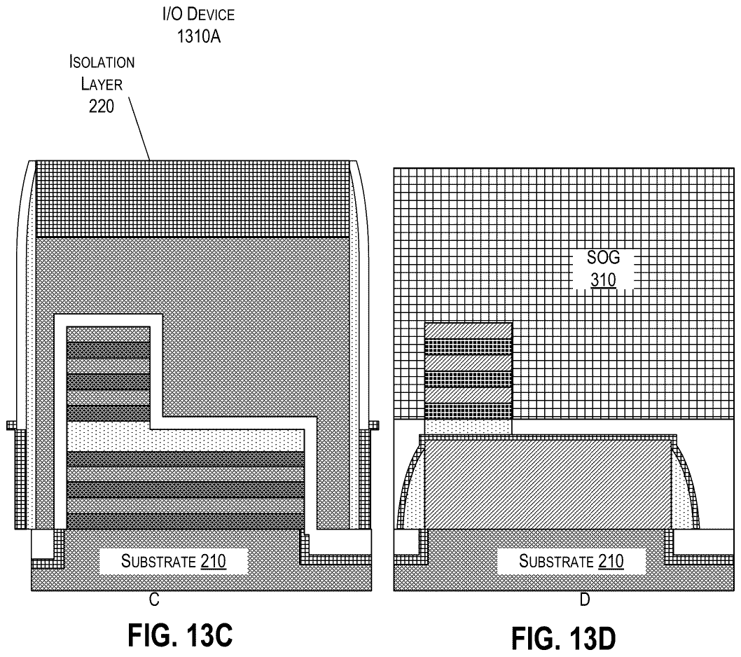

FIGS. 13A-13D illustrate a semiconductor device after removal of the spacer, in accordance with some embodiments. In some embodiments, the spacer is removed from the semiconductor device. It should be noted that, one I/O device 1310A and the logic device 1320 remain blocked and the spacer is removed from the other I/O device, I/O device 1310B.

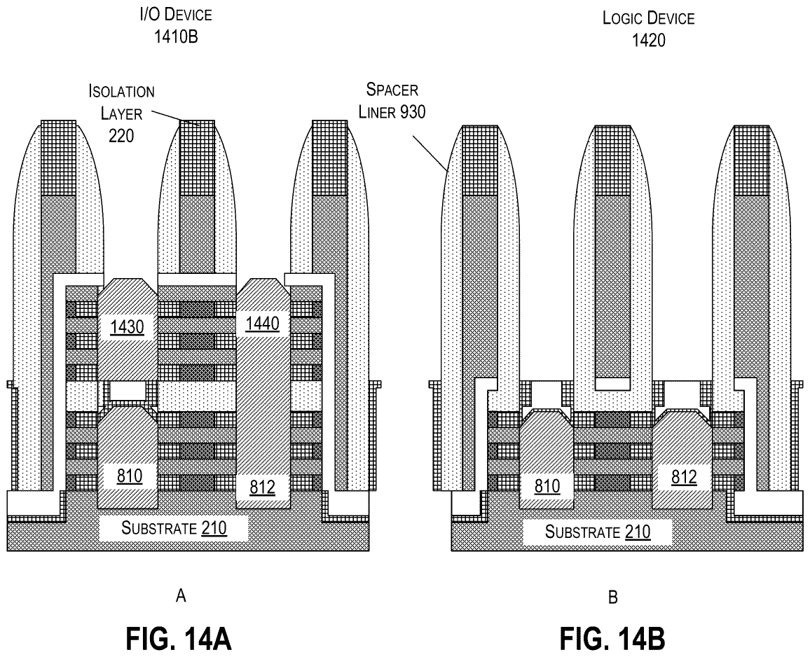

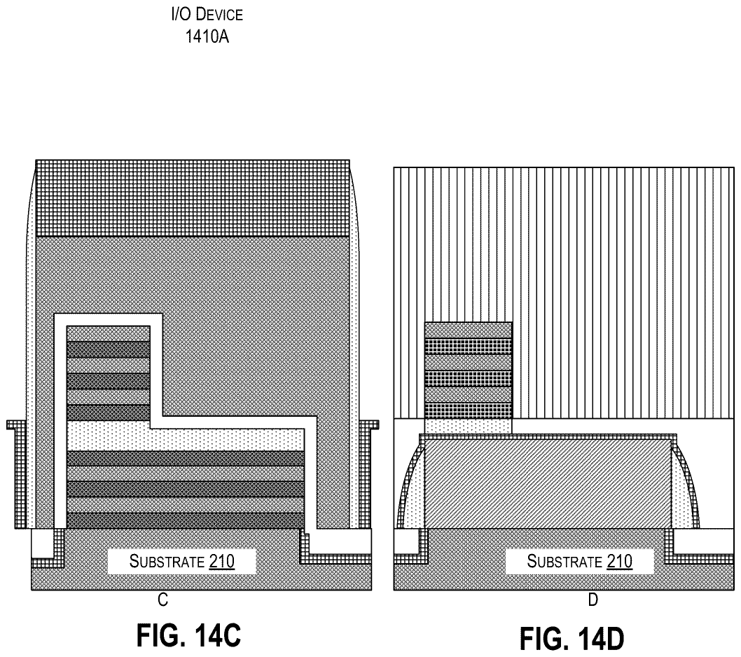

FIGS. 14A-14D illustrate a semiconductor device after formation of the top source and drain regions, in accordance with some embodiments. In some embodiments, the top source region 1430 and the top drain region 1440 are formed. It should be noted that, one I/O device 1410B and the logic device 1420 remain blocked and the top source region 1430 and the top drain region 1440 are formed in the other I/O device, I/O device 1410A. By merging the top drain region and the bottom source region, the semiconductor device achieves a serial connection between two field-effect transistors (FETs) without the need for an additional contact. In the device structure, the top source region is positioned over the bottom drain region, and the top drain region is located over the bottom source region. By merging the epitaxial layers of the bottom drain region and the top source region, a continuous semiconductor path is created between them. Such a physical and electrical connection allows current to flow directly from the bottom transistor's drain to the top transistor's source, effectively connecting the two transistors in series. As such, no additional contact is required to connect the two transistors. Typically, connecting transistors in series would involve forming metal contacts and interconnects, which add complexity to the fabrication process and can introduce parasitic resistances and capacitances that degrade the device's performance. By eliminating the need for these contacts, the merged epitaxial layers reduce parasitic effects, leading to improved electrical performance such as faster switching speeds and lower power consumption.

Additionally, removing the requirement for extra contacts simplifies the fabrication process. Contacts and interconnects necessitate additional lithography, deposition, and etching steps, which increase manufacturing complexity and cost. Simplifying the process reduces the potential for defects and improves overall yield and reliability of the semiconductor device. The method further contributes to compact device architecture. Serially connecting transistors through merged epitaxial layers allows for vertical stacking of devices without expanding the chip's footprint, which is beneficial in advanced semiconductor technologies where space is at a premium, and higher device density is desired for integrating more functionality into a single chip.

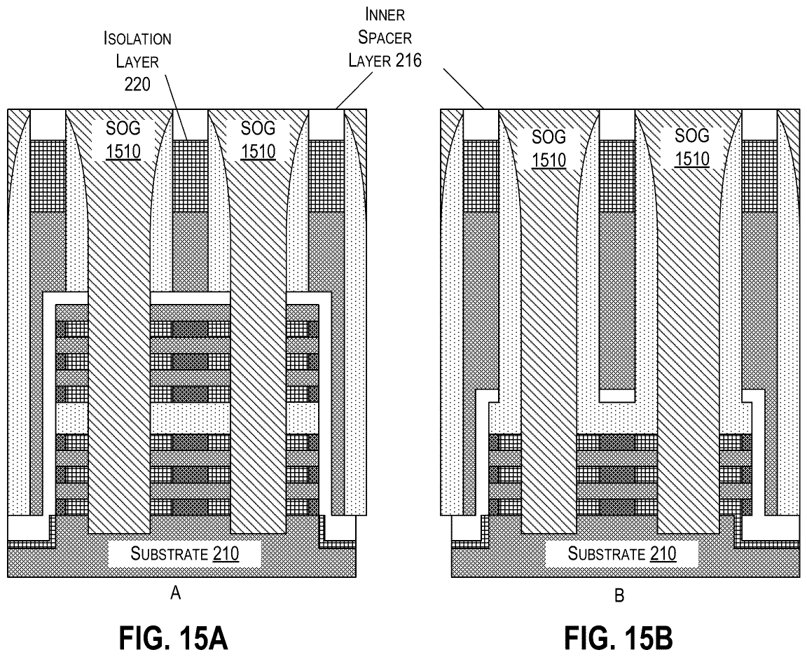

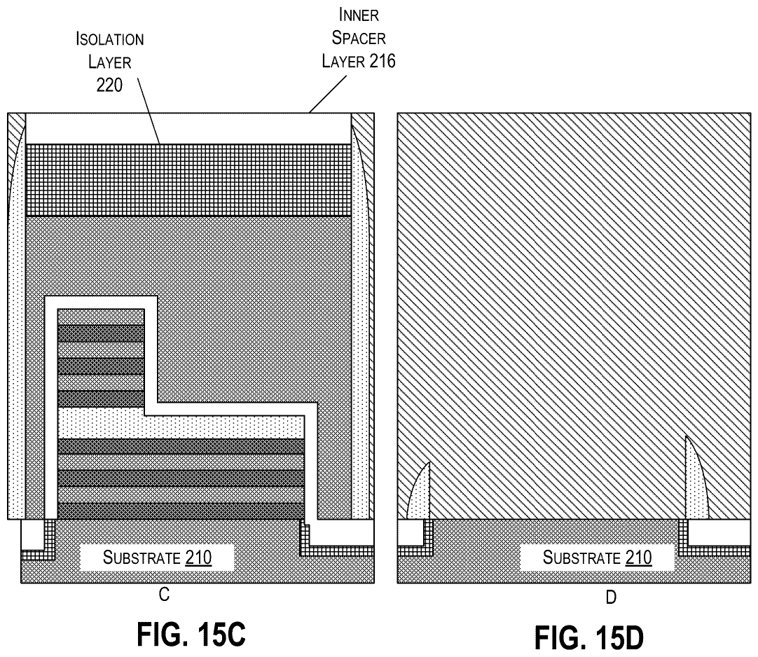

FIGS. 15-30 illustrate various acts in the manufacture of a semiconductor device with the focus on the fabrication of the type A, e.g., an PFET, I/O device, consistent with illustrative embodiments.

FIGS. 15A-15D illustrate a semiconductor device after the formation of the spin on glass, in accordance with some embodiments. In some embodiments, the spin on glass, SOG 1510, is formed over the semiconductor device.

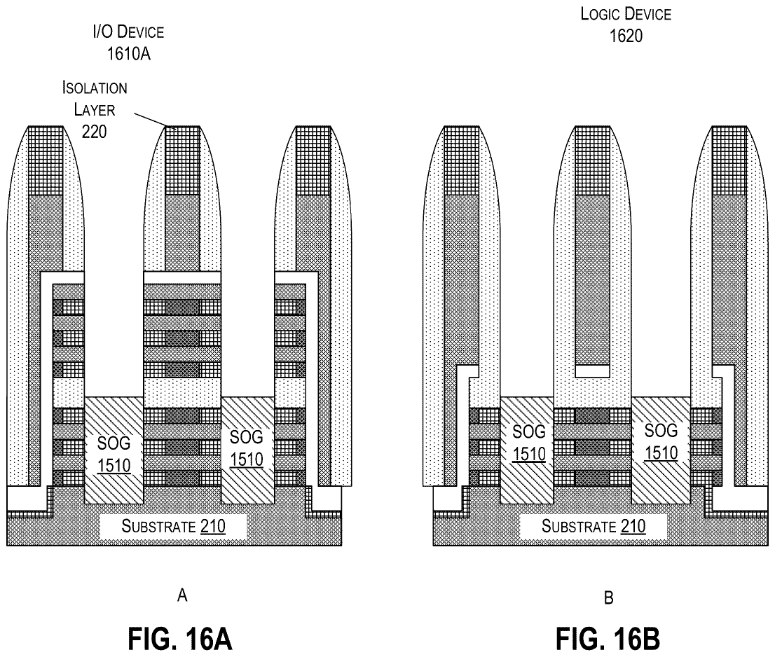

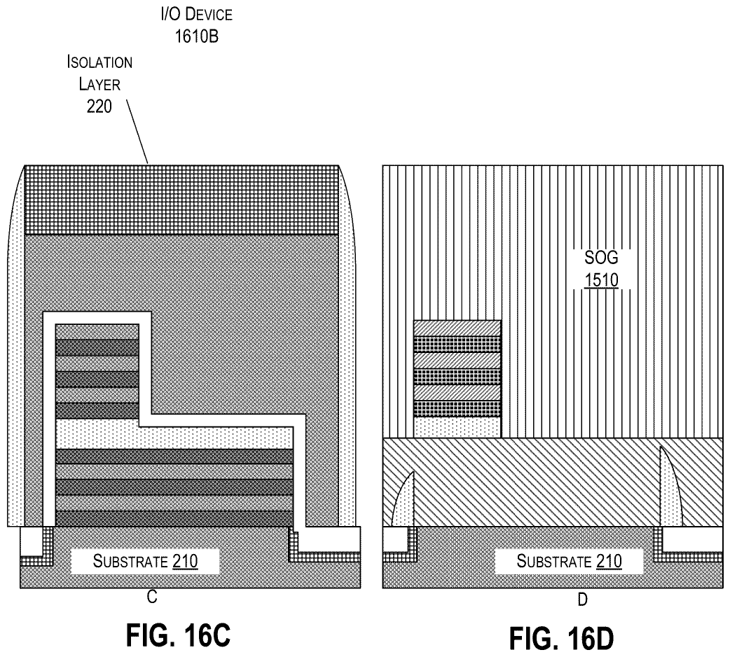

FIGS. 16A-16D illustrate a semiconductor device after the removal of portions of the spin on glass, in accordance with some embodiments. In some embodiments, portions of the SOG are removed from the semiconductor device. It should be noted that, one I/O device 1610B and the logic device 1620 remain blocked and portions of the SOG are removed from the other I/O device, I/O device 1610A.

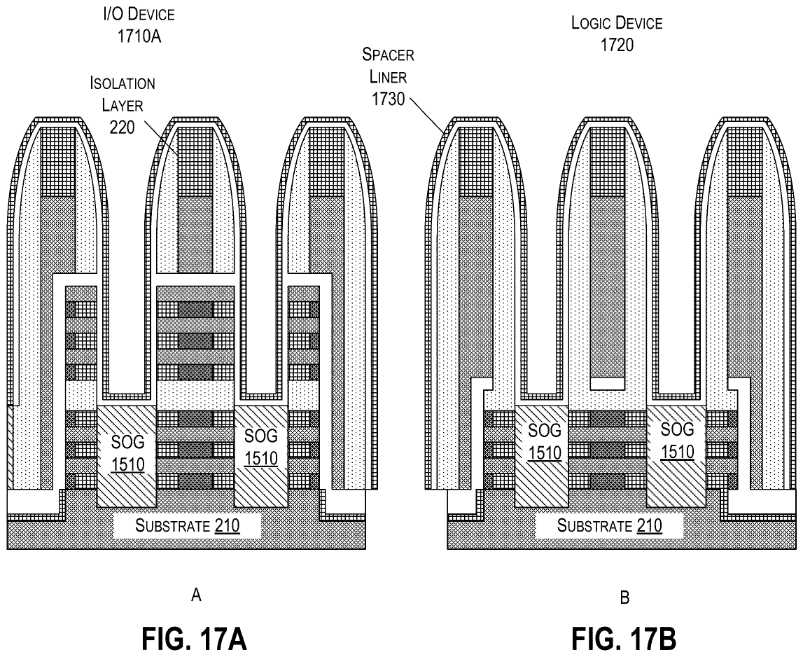

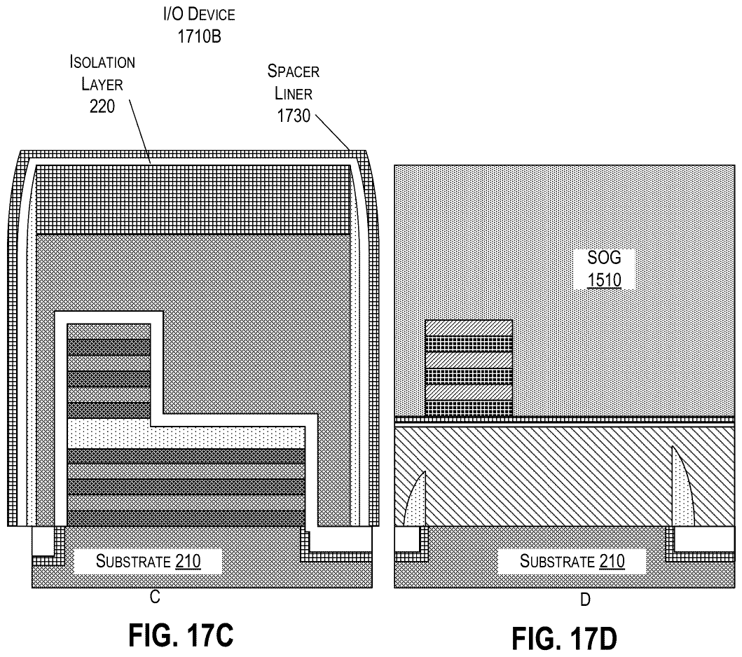

FIGS. 17A-17D illustrate a semiconductor device after the formation of the spacer liner, in accordance with some embodiments. In some embodiments, the spacer liner 1730 is formed over the semiconductor device. It should be noted that, one I/O device 1710B and the logic device 1720 remain blocked and the spacer liner 1730 is formed over the other I/O device, I/O device 1710A.

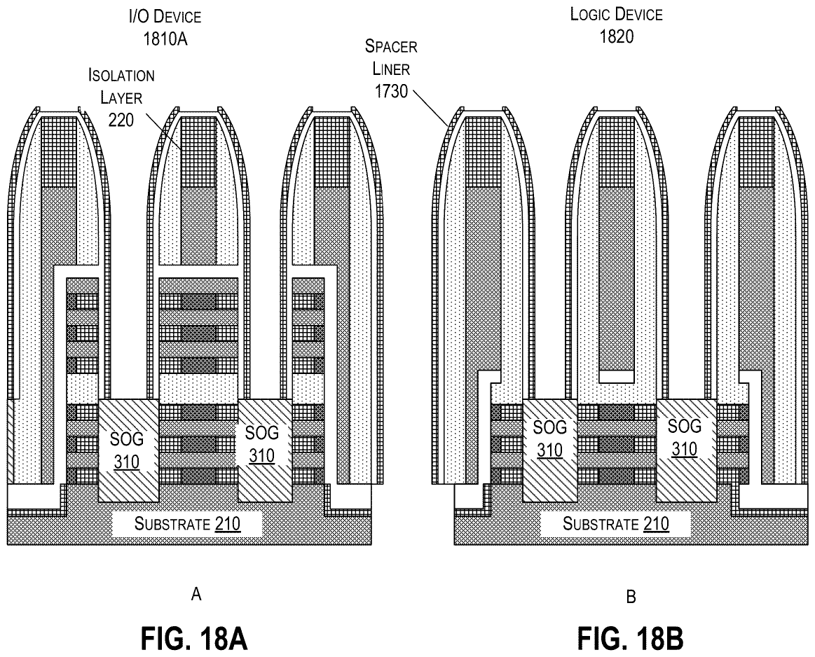

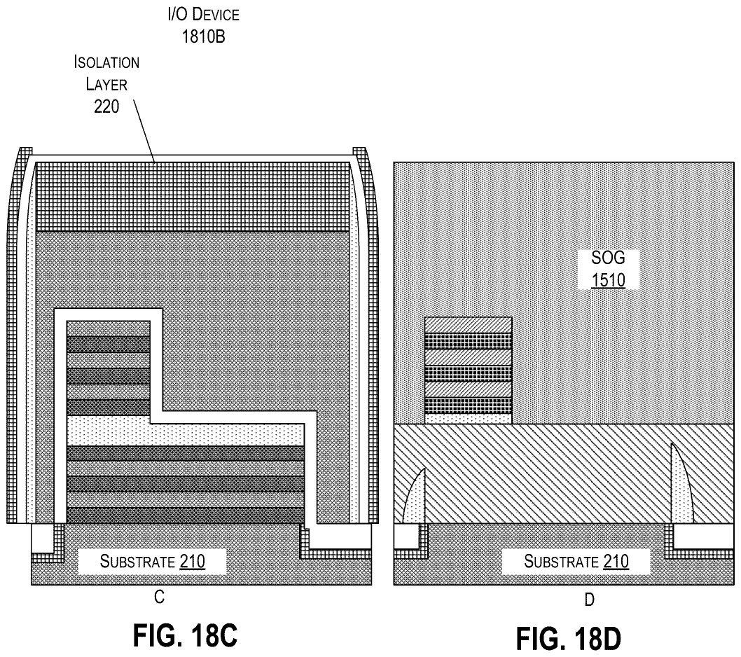

FIGS. 18A-18D illustrate a semiconductor device after the partial removal of the spacer liner, in accordance with some embodiments. In some embodiments, the spacer liner over the top surfaces of the semiconductor device are removed. It should be noted that, one I/O device 1810A and the logic device 1820 remain blocked and the spacer liner is removed from the top surfaces of the other I/O device, I/O device 1810B. A reactive ion etching (RIE) technique can be performed to remove the spacer liner.

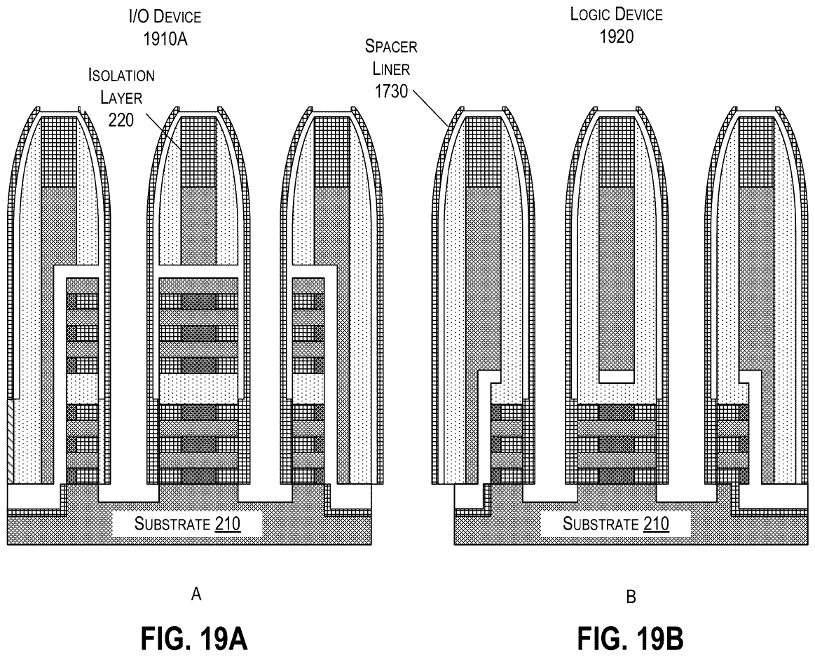

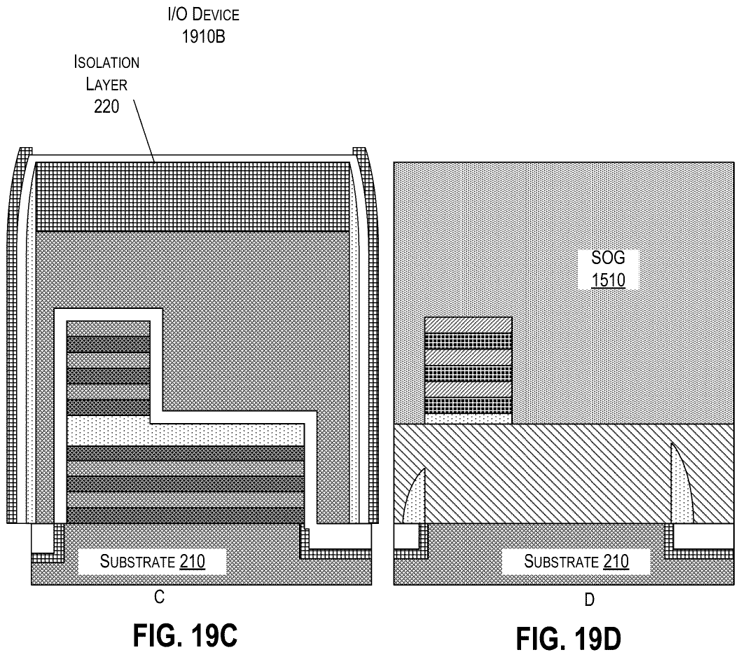

FIGS. 19A-19D illustrate a semiconductor device after the stripping the spin on glass, in accordance with some embodiments. In some embodiments, the remaining SOG are removed. It should be noted that, one I/O device 1910B and the logic device 1920 remain blocked and the SOG is removed from the top surfaces of the other I/O device, I/O device 1910A.

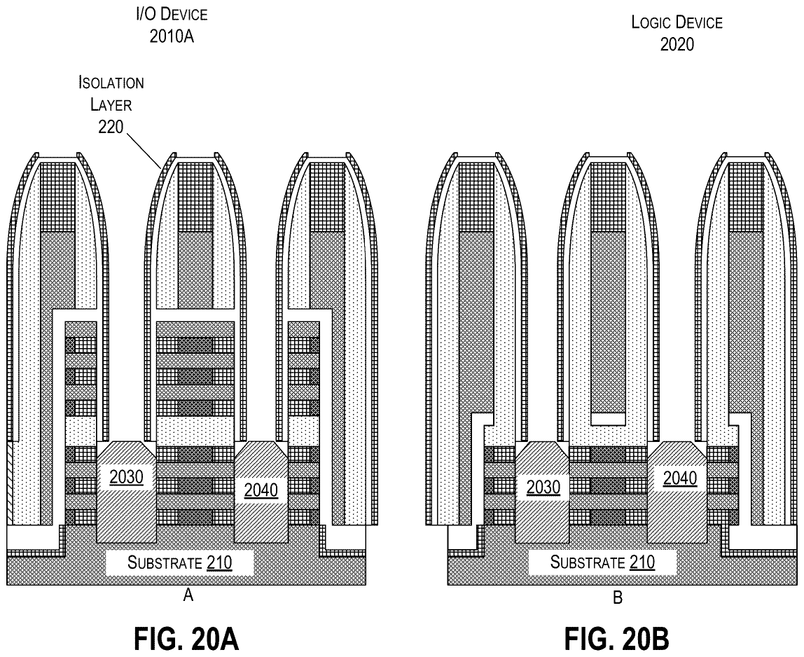

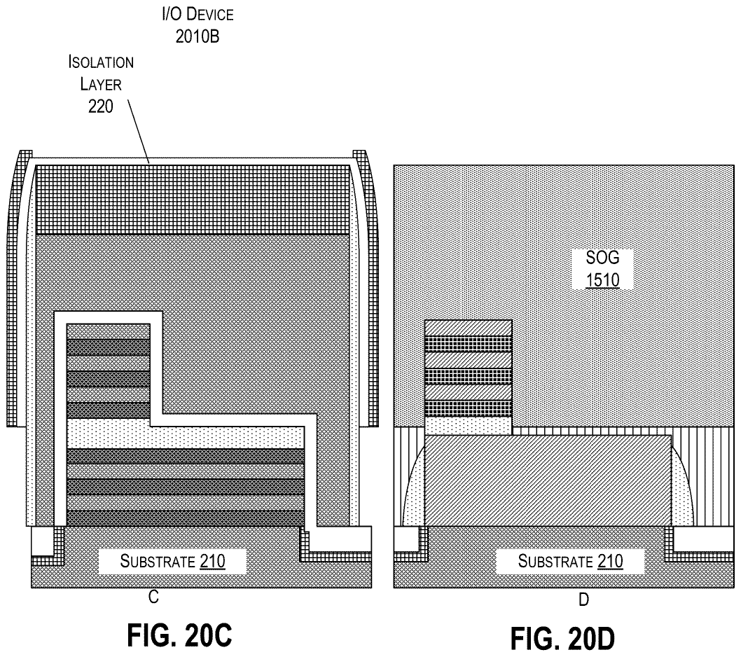

FIGS. 20A-20D illustrate a semiconductor device after the formation of the bottom source and drain regions, in accordance with some embodiments. In some embodiments, the bottom source region 2030 and the bottom drain region 2040 are formed. It should be noted that, one I/O device 2010B and the logic device 2020 remain blocked and the bottom source and drain are formed over the other I/O device, I/O device 2010A.

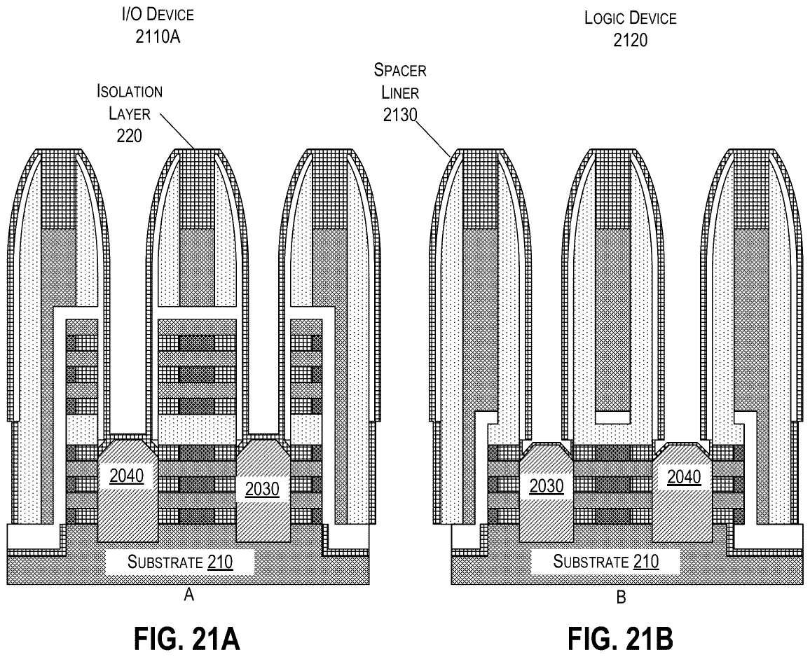

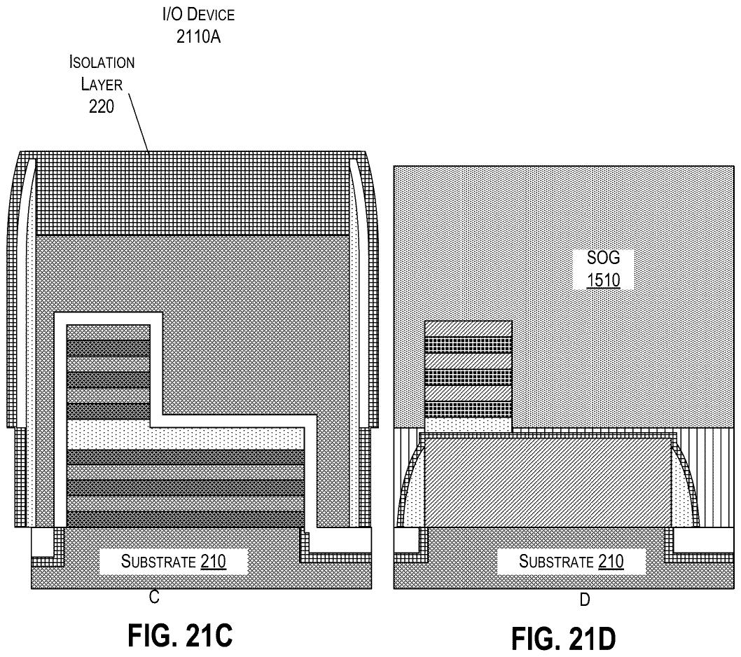

FIGS. 21A-21D illustrate a semiconductor device after the formation of the liner layer, in accordance with some embodiments. In some embodiments, the spacer liner 2130 is formed over the semiconductor device. It should be noted that, one I/O device 2110B and the logic device 2120 remain blocked and the liner layer is formed over the other I/O device, I/O device 2110A.

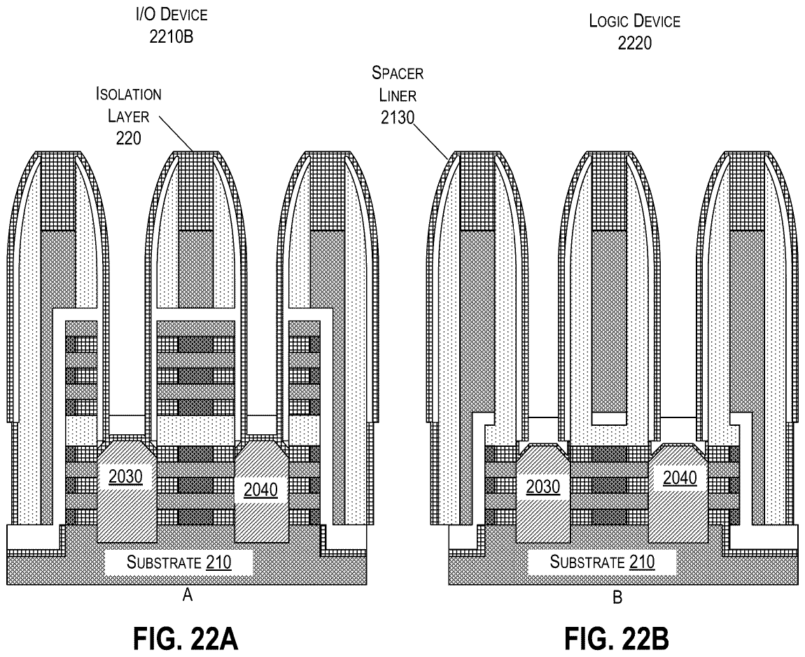

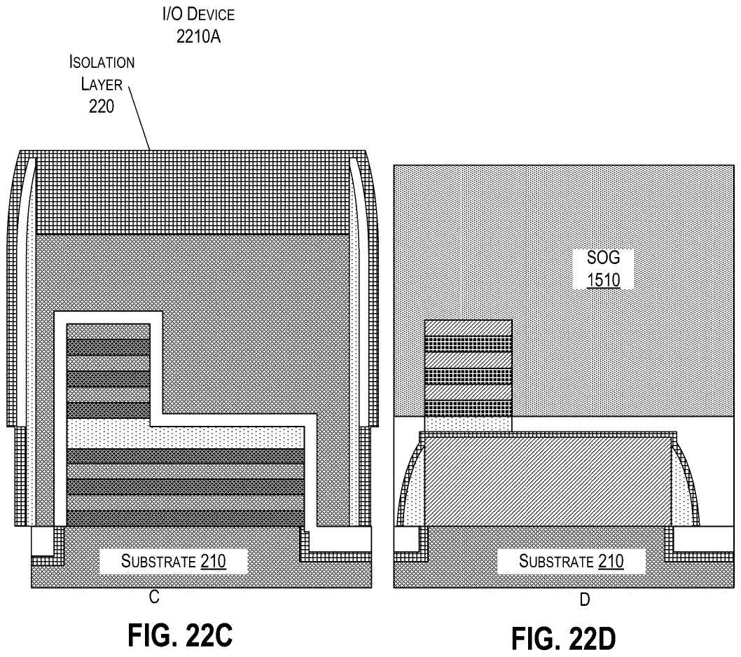

FIGS. 22A-22D illustrate a semiconductor device after the high aspect ratio process, in accordance with some embodiments. A flowable chemical vapor deposition (FCVD) and high aspect ratio process (HARP) deposition can be performed. It should be noted that, one I/O device 2210B and the logic device 2220 remain blocked and the bottom source and drain are formed over the other I/O device, I/O device 2210A.

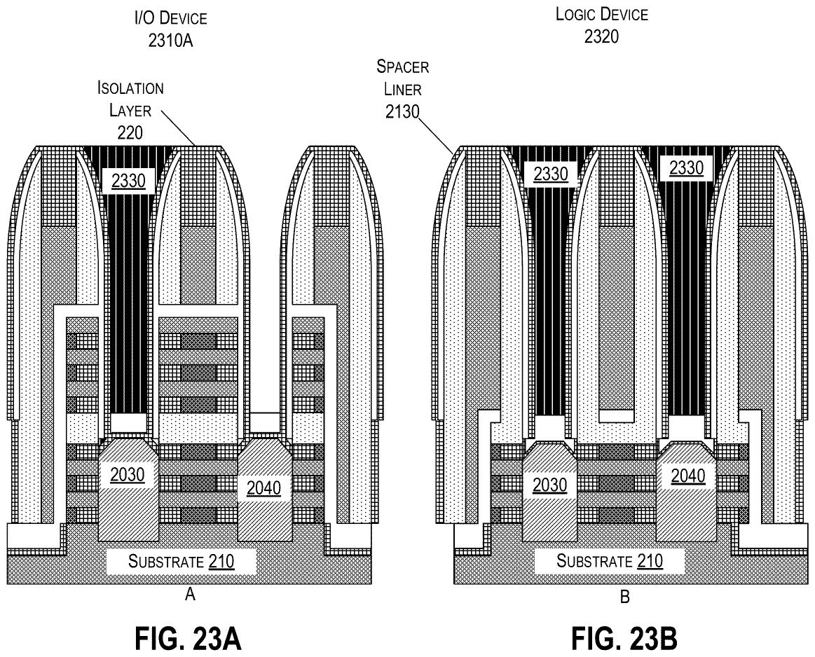

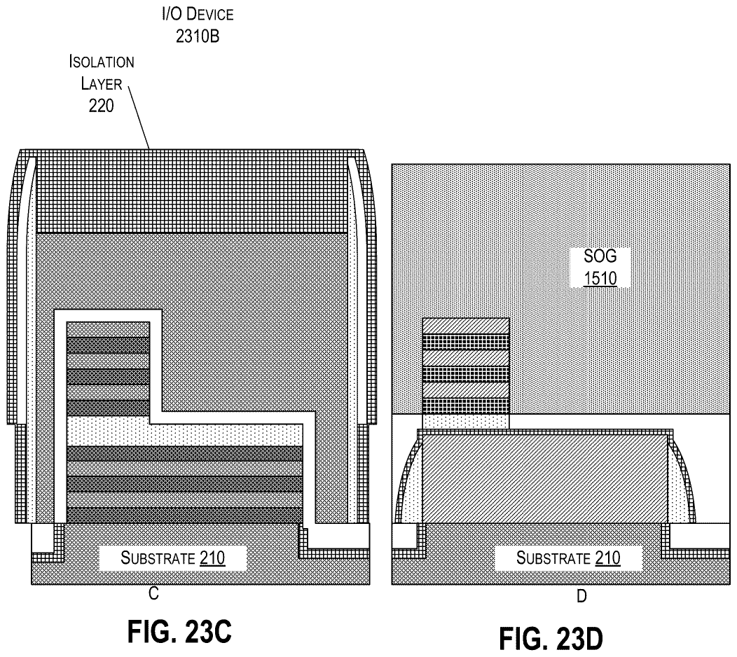

FIGS. 23A-23D illustrate a semiconductor device after blocking the semiconductor device, in accordance with some embodiments. In some embodiments, the semiconductor device, the I/O device 2310A and I/O device 2320, except the drain region of the I/O device 2310B, are blocked by a suitable material such as SiN blocking spacer 2330.

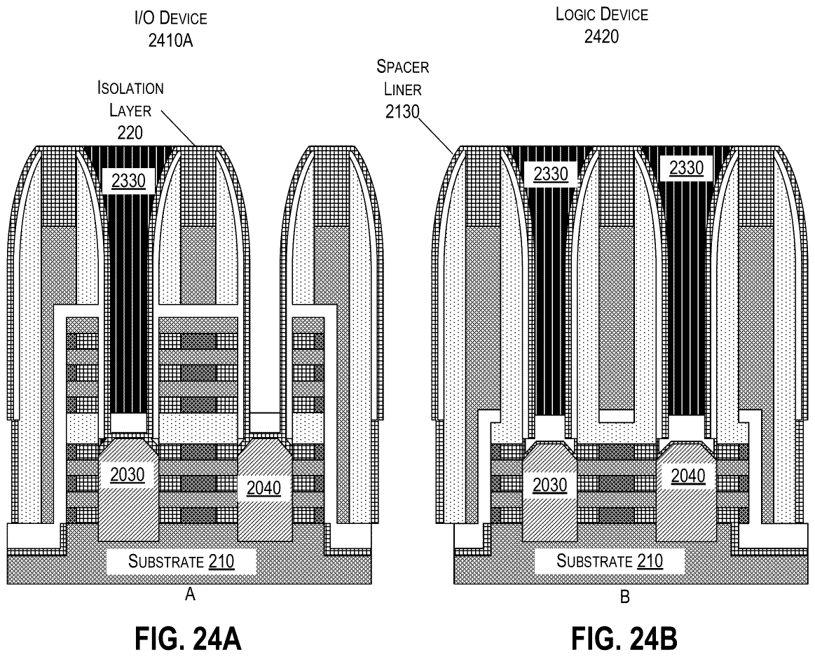

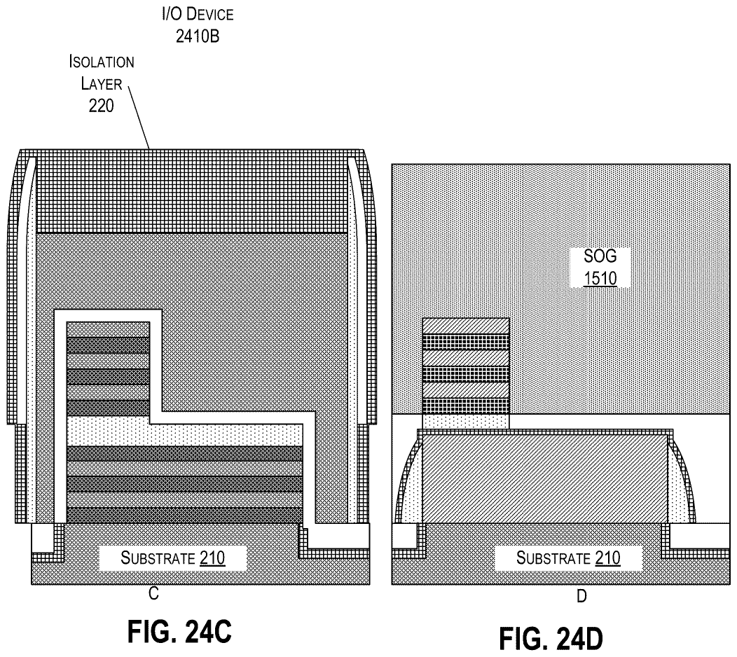

FIGS. 24A-24D illustrate a semiconductor device after removal of the oxide layer, in accordance with some embodiments. In some embodiments, the oxide layer is removed from the stacked portion of one of the I/O devices, e.g., I/O device 2410A, of the semiconductor device. It should be noted that, one I/O device 2410B and the logic device 2420 remain blocked and the oxide layer is removed from the other I/O device, I/O device 2410A.

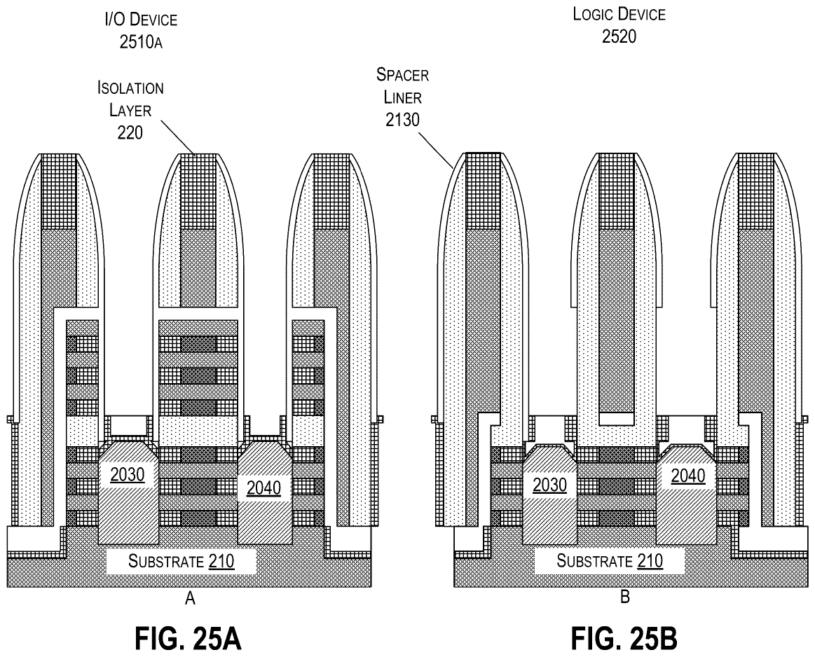

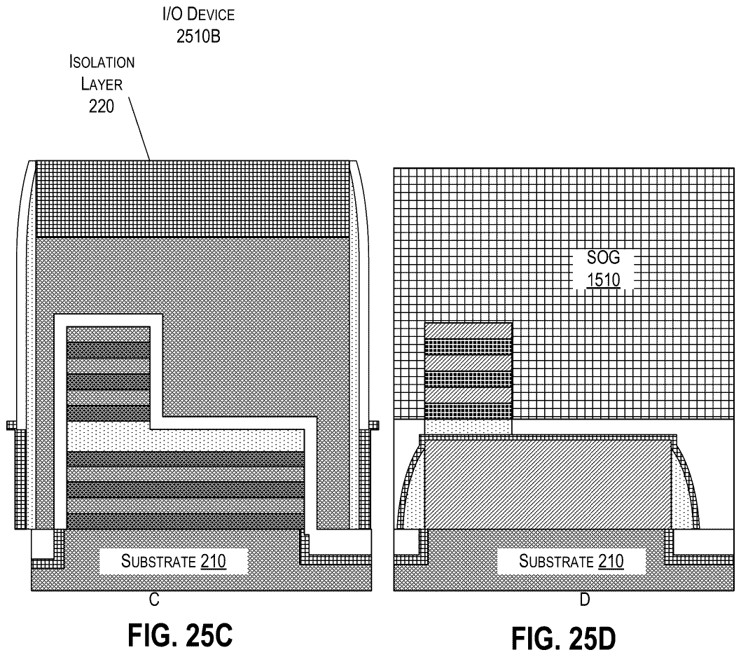

FIGS. 25A-25D illustrate a semiconductor device after removal of the blocking spacer layer, in accordance with some embodiments. In some embodiments, the blocking spacer layer is removed from the I/O device 2510A. It should be noted that, one I/O device 2510B and the logic device 2520 remain blocked and the blocking spacer layer 1120 is removed from the other I/O device, I/O device 2510A.

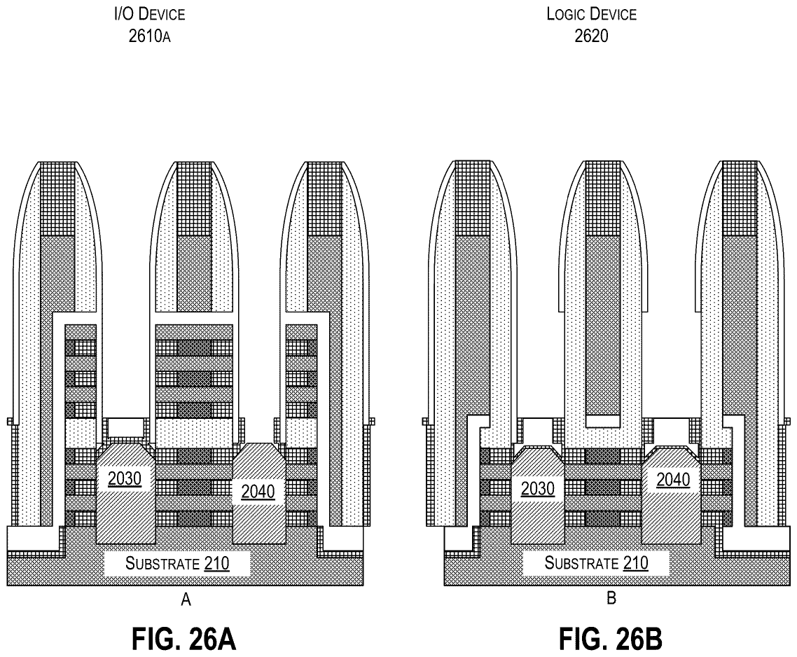

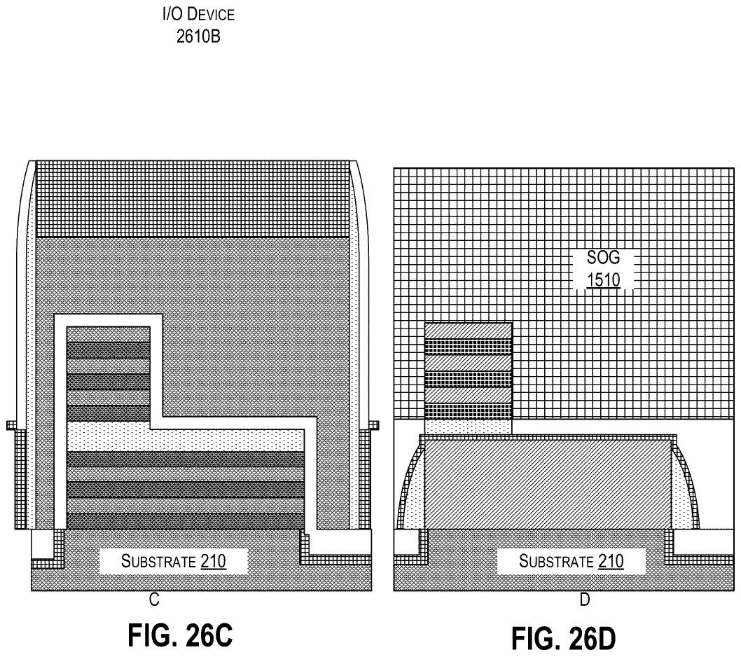

FIGS. 26A-26D illustrate a semiconductor device after removal of the blocking spacer layer, in accordance with some embodiments. In some embodiments, the blocking spacer layer is removed from the logic device 2620. It should be noted that, the I/O device 2610A and the I/O device 2610B remain blocked and the blocking spacer layer 1120 is removed from the logic device 2620.

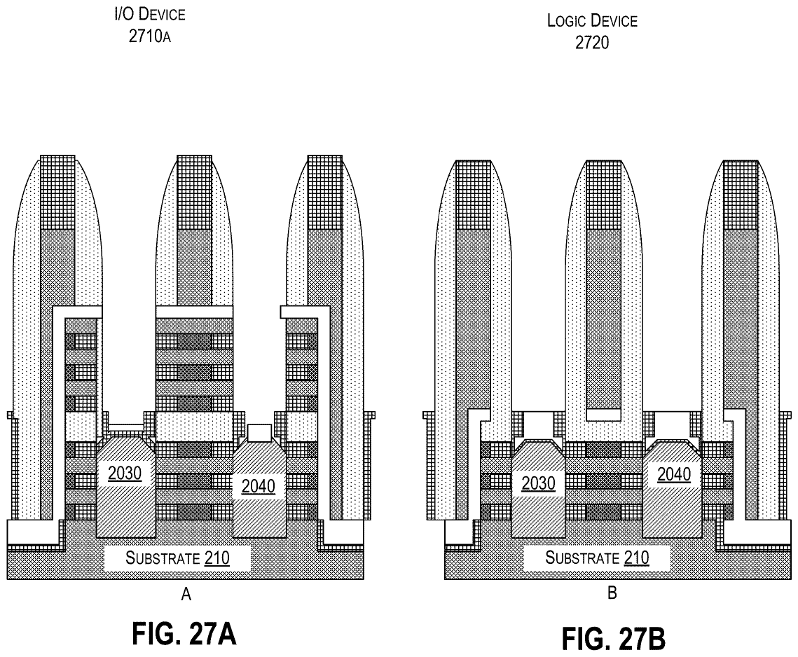

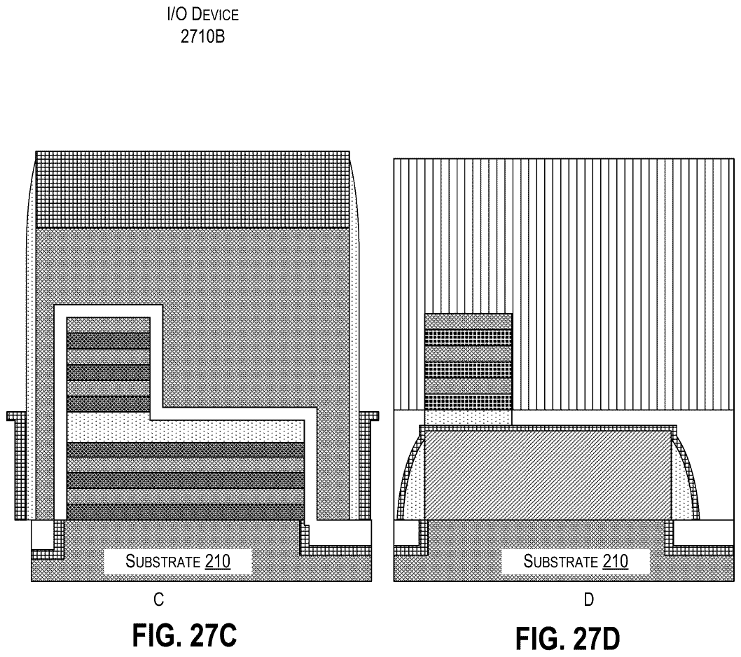

FIGS. 27A-27D illustrate a semiconductor device after removal of the spacer, in accordance with some embodiments. In some embodiments, the spacer is removed from the semiconductor device. It should be noted that, one I/O device 2710B and the logic device 2720 remain blocked and the spacer 1330 is removed from the other I/O device, I/O device 2710A.

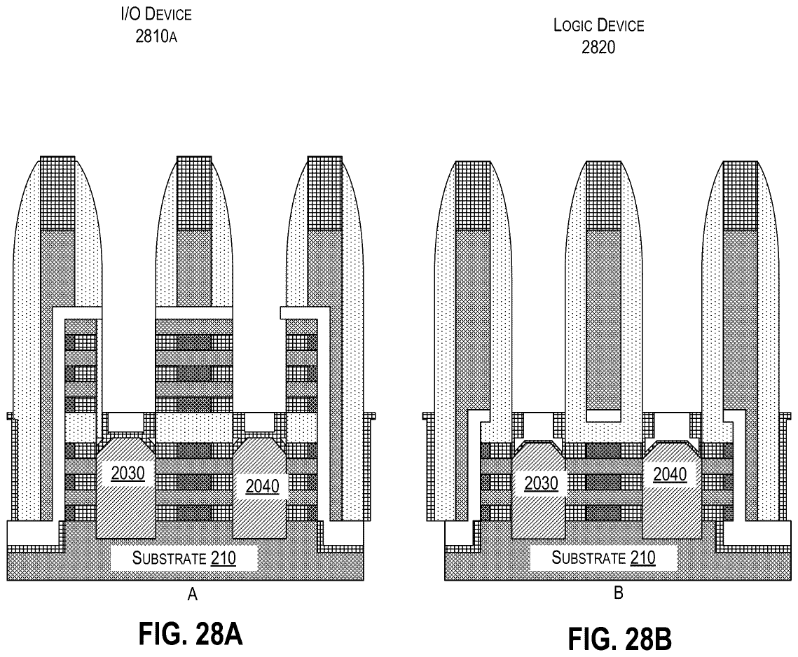

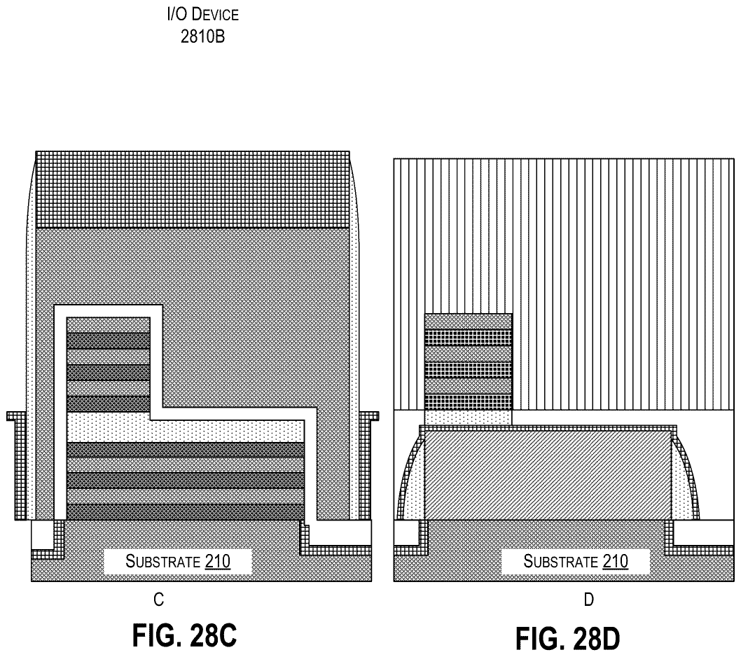

FIGS. 28A-28D illustrate a semiconductor device after removal of the spacer, in accordance with some embodiments. In some embodiments, the spacer is removed from the semiconductor device. It should be noted that, the I/O device 2810B and the I/O device 2810A remain blocked and the spacer 1330 is removed from the logic device 2820.

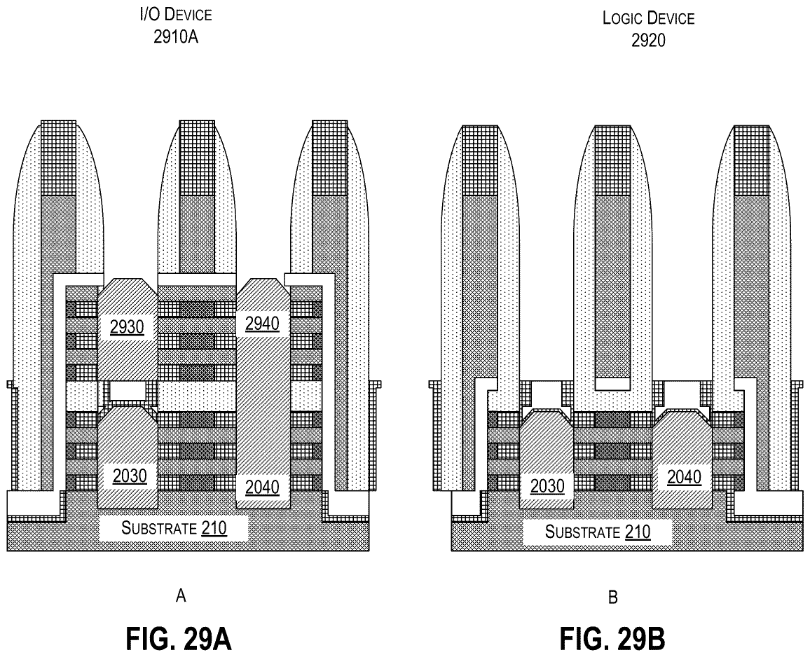

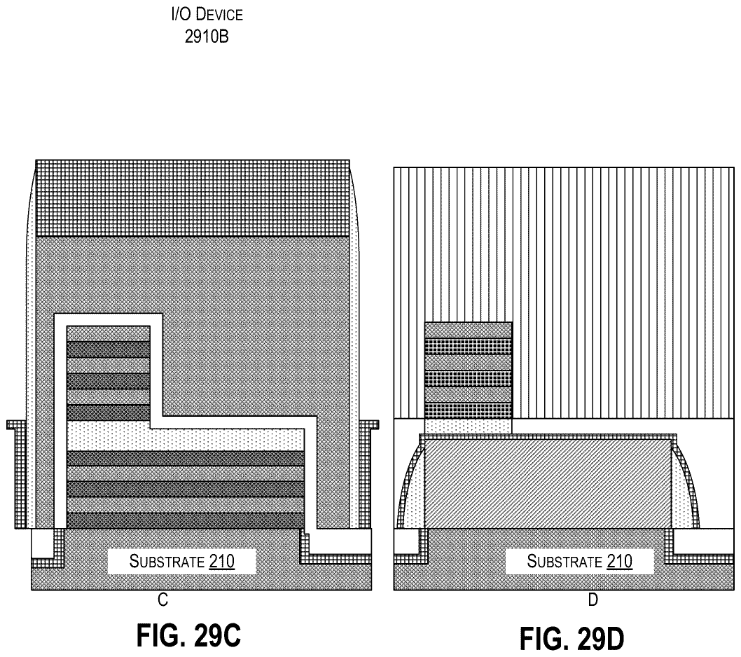

FIGS. 29A-29D illustrate a semiconductor device after formation of the top source and drain regions, in accordance with some embodiments. In some embodiments, the top source region 2930 and the top drain region 2940 are formed. It should be noted that, one I/O device 2910A and the logic device 2920 remain blocked and the top source region 2930 and the top drain region 2940 are formed in the other I/O device, I/O device 2910B.

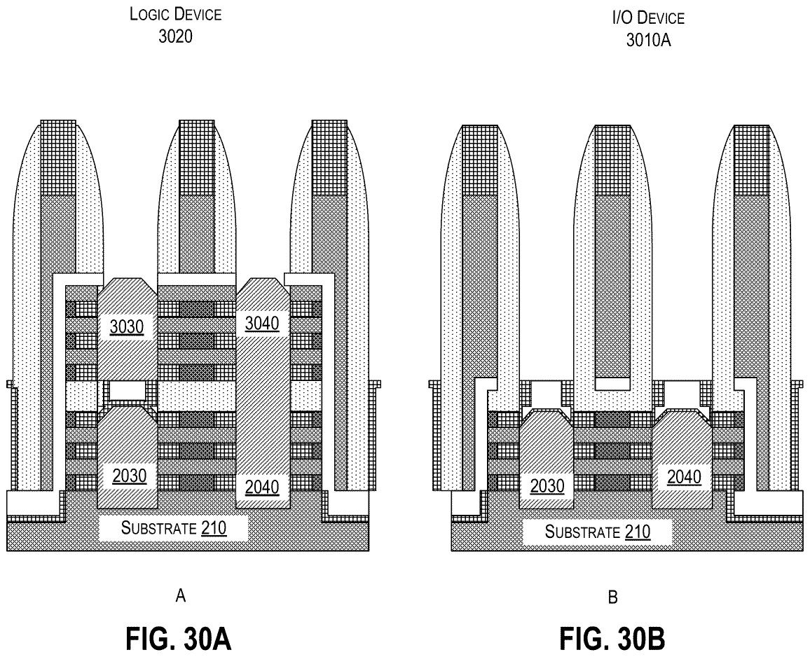

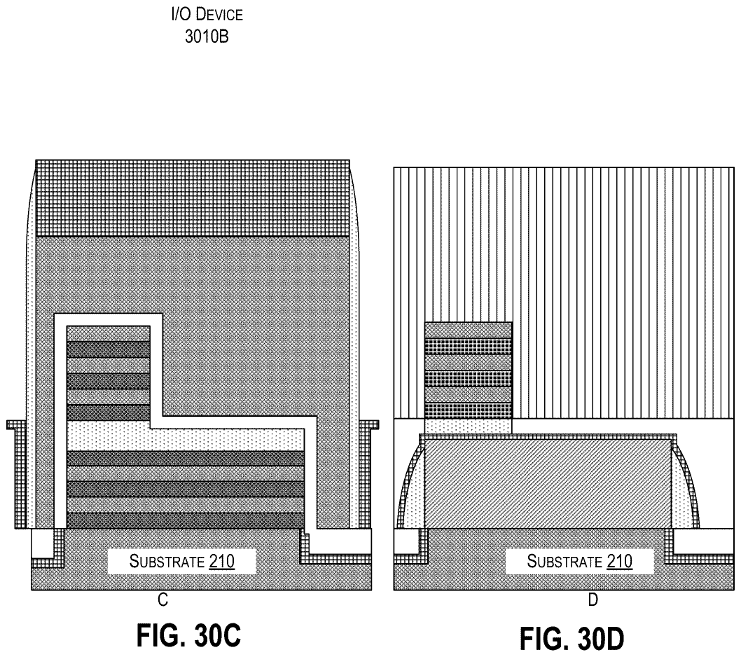

FIGS. 30A-30D illustrate a semiconductor device after formation of the top source and drain regions, in accordance with some embodiments. In some embodiments, the top source region 3030 and the top drain region 3040 are formed in the logic device 3020. It should be noted that, the I/O device 3010A and the I/O device 3010B remain blocked and the top source region 3030 and the top drain region 3040 are formed in the logic device 3020.

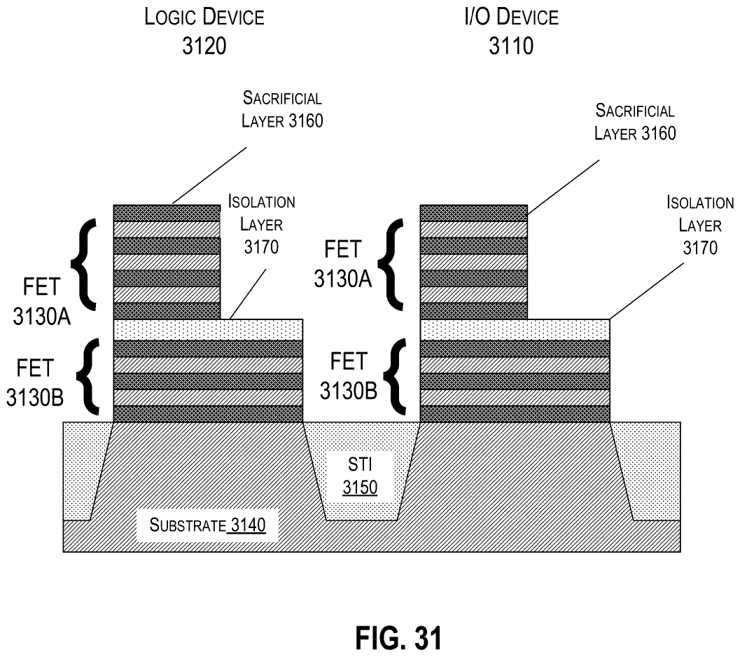

FIGS. 31-43 illustrate various acts in the manufacture of a semiconductor device with the focus on the fabrication of the gate regions, consistent with illustrative embodiments.

Referring to FIG. 31, the semiconductor device can include a logic device 3120 and an I/O device 3110. Each of the logic device 3120 and the I/O device 3110 can include a top FET 3130A, a bottom FET 3130B, a substrate 3140, an isolation layer 3170 separating, e.g., isolating, the top FET 3130A and the bottom FET 3130B, STI 3150, and a sacrificial layer 3160. It should be noted that, the source regions and the drain regions can be formed but are not shown as the source and drain regions are in an in-out paper direction.

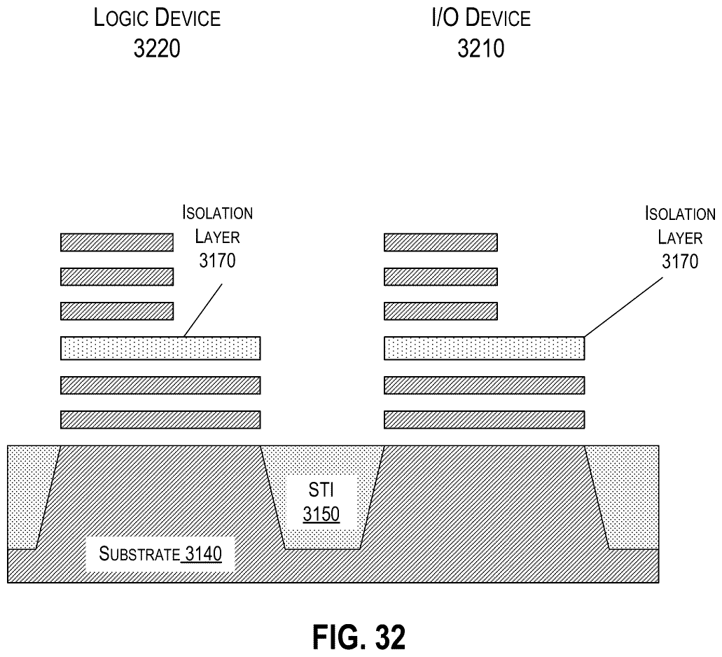

FIG. 32 illustrates a semiconductor device after the selective removal of the sacrificial layer, in accordance with some embodiments. In some embodiments, the sacrificial layer is removed from the I/O device 3210 and the logic device 3220. The sacrificial layer can be removed by an HCl solution.

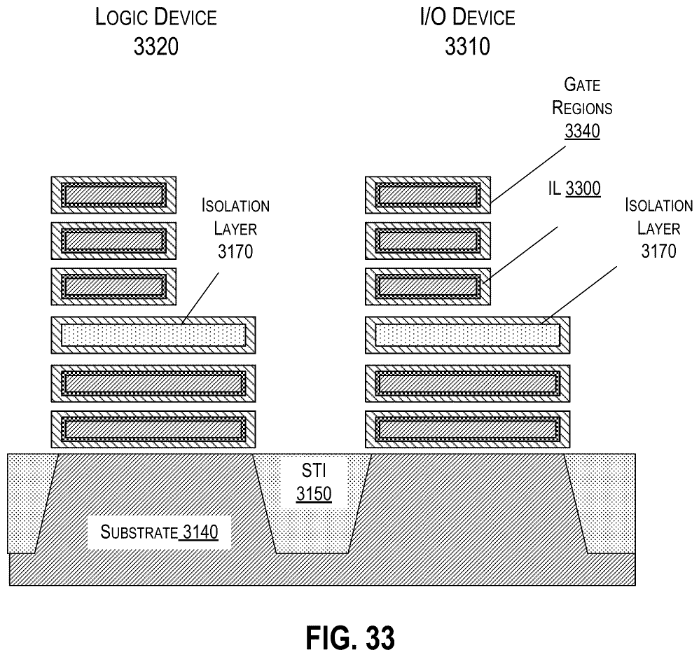

FIG. 33 illustrates a semiconductor device after the formation of the interfacial layer, in accordance with some embodiments. In some embodiments, the interfacial layer, IL 3300, and the gate regions 3340 are formed over I/O device 3310 and the logic device 3320. In some embodiments, a replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

In various embodiments, the gate regions 3340 serve as control elements that regulate the flow of current through the semiconductor device. The gate regions 3340 can be composed of a conductive material. The gate regions 3340 can control the flow of electric current between the source and drain regions. In addition to acting as a switch, modulating the gate voltage can enable the gate regions 3340 to control the current flowing through the channel region, resulting in amplified output signals. In an embodiment, the gate regions 3340 can enable the implementation of Boolean active operations, such as AND, OR, and NOT, by controlling the flow of current based on the input voltages. In some embodiments, the gate regions 3340, along with other active device components, can facilitate the miniaturization and integration of electronic circuits. The ability to control the channel region's conductivity through the gate voltage allows for compact and highly efficient circuit designs.

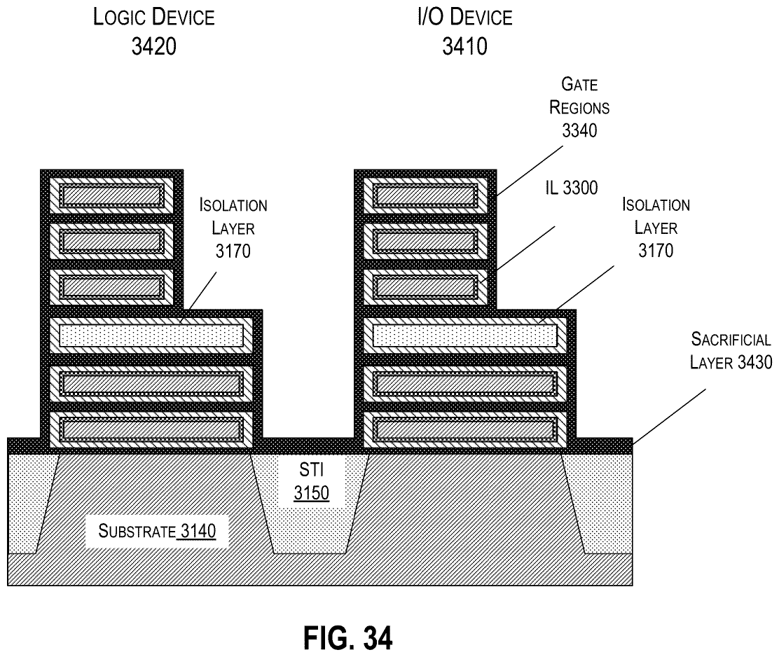

FIG. 34 illustrates a semiconductor device after the formation of the sacrificial layer, in accordance with some embodiments. In some embodiments, a sacrificial layer 3430 is formed over the semiconductor device, e.g., the logic device 3420 and the I/O device 3410. The process involves depositing a thick sacrificial capping layer, such as oxygen-rich titanium nitride (TiN), onto the semiconductor device to enhance reliability during fabrication. The sacrificial layer 3430 can be made thick to “pinch off” the spacing between nanoscale channels in the device. By filling and sealing the gaps between channels, the thick capping layer prevents unwanted materials or contaminants from penetrating into sensitive regions during subsequent processing steps. The oxygen-rich TiN promotes the selective growth of the IL 3400 specifically in the I/O device regions during thermal treatments. The IL 3400 allows the I/O devices to handle higher voltages without degrading the performance of the logic device regions, which require thinner gate dielectrics for optimal operation.

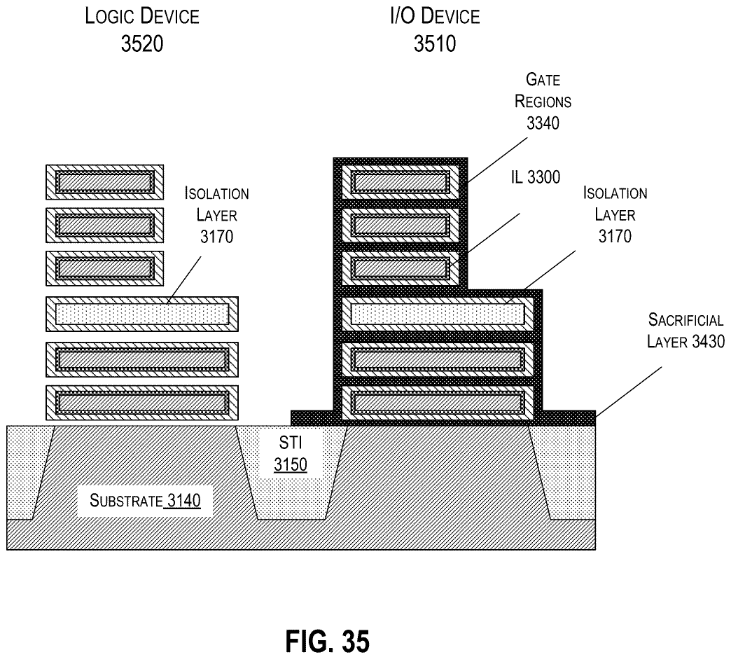

FIG. 35 illustrates a semiconductor device after the removal of the sacrificial layer, in accordance with some embodiments. In some embodiments, the sacrificial layer is removed from the logic device 3520 but not from the I/O device 3510.

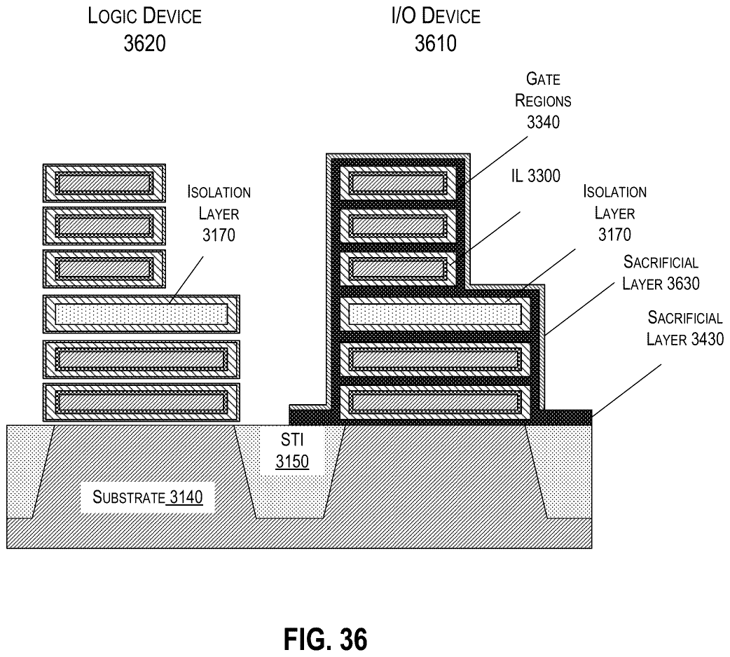

FIG. 36 illustrates a semiconductor device after the formation of the additional sacrificial layer, in accordance with some embodiments. In some embodiments, an additional sacrificial layer 3630 is formed over the semiconductor device, e.g., the logic device 3620 and the I/O device 3610. The additional sacrificial layer 3630 can be made of TiN.

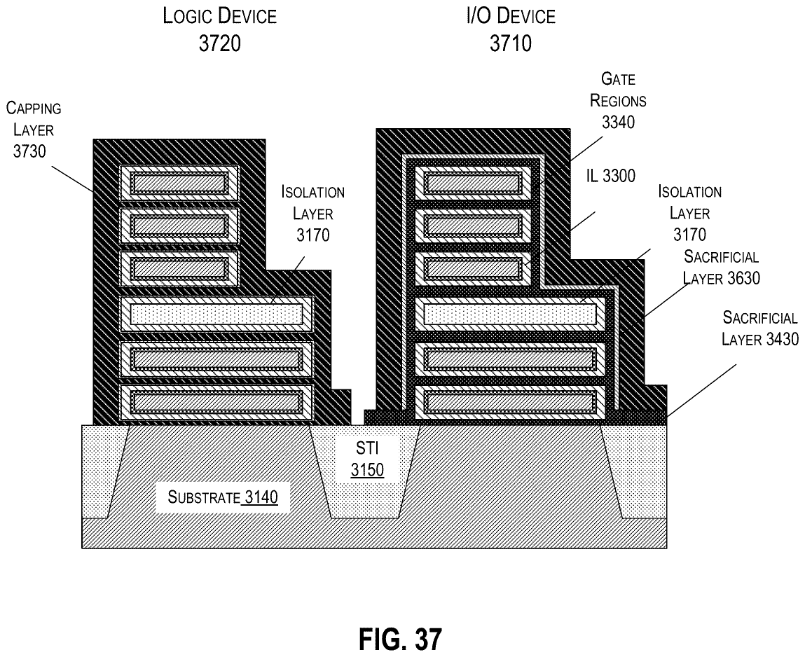

FIG. 37 illustrates a semiconductor device after the formation of the capping layer, in accordance with some embodiments. In some embodiments, a capping layer 3730 is formed over the additional sacrificial layer 3630 in the logic device 3720 and the I/O device 3710. The capping layer 3730 can block oxygen from the environment.

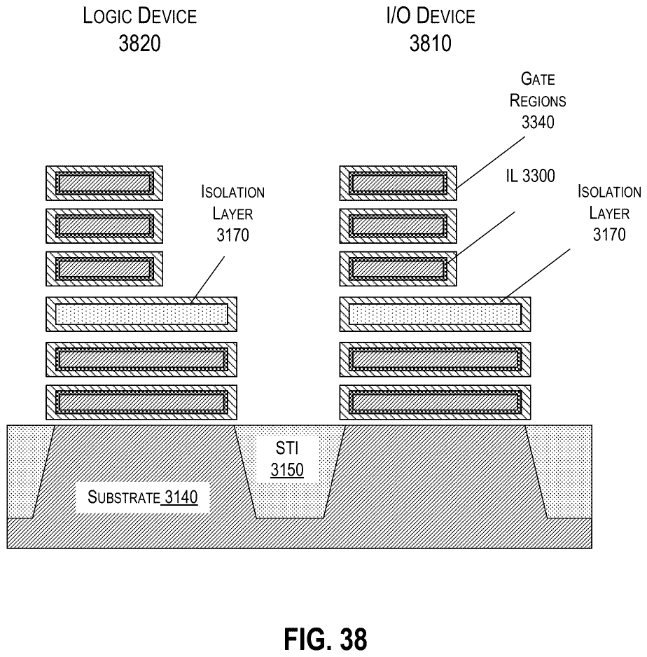

FIG. 38 illustrates a semiconductor device after the annealing, in accordance with some embodiments. In some embodiments, an annealing process can be performed and all of the sacrificial layers can be removed from the logic device 3820 and the I/O device 3810.

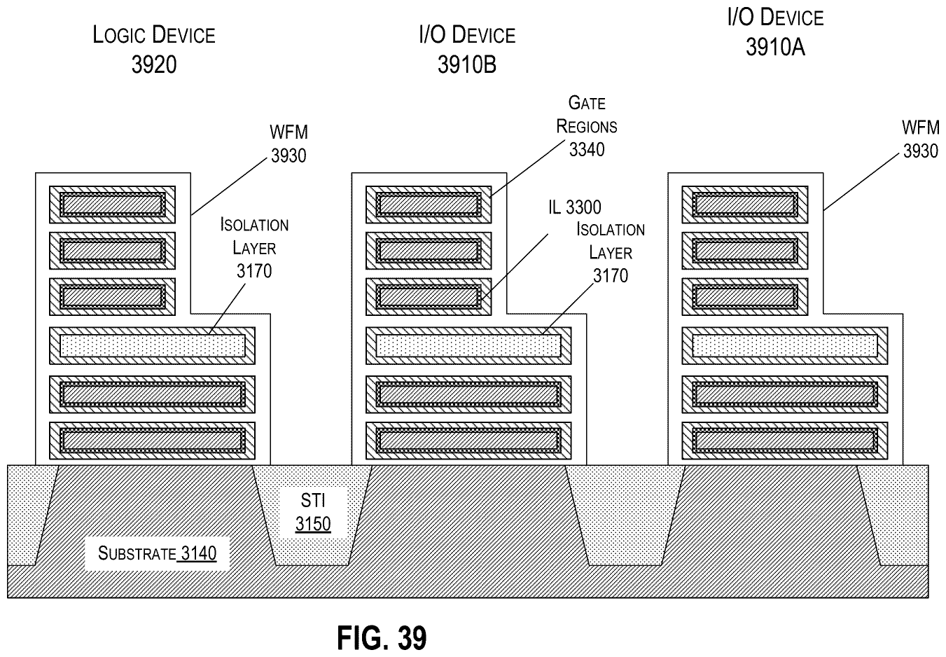

FIG. 39 illustrates a semiconductor device after the formation of the work function metal, in accordance with some embodiments. In some embodiments, a work function metal, WFM 3930, is formed over the gate regions 3340 in the logic device 3920, the I/O device 3910A, and the I/O device 3910B.

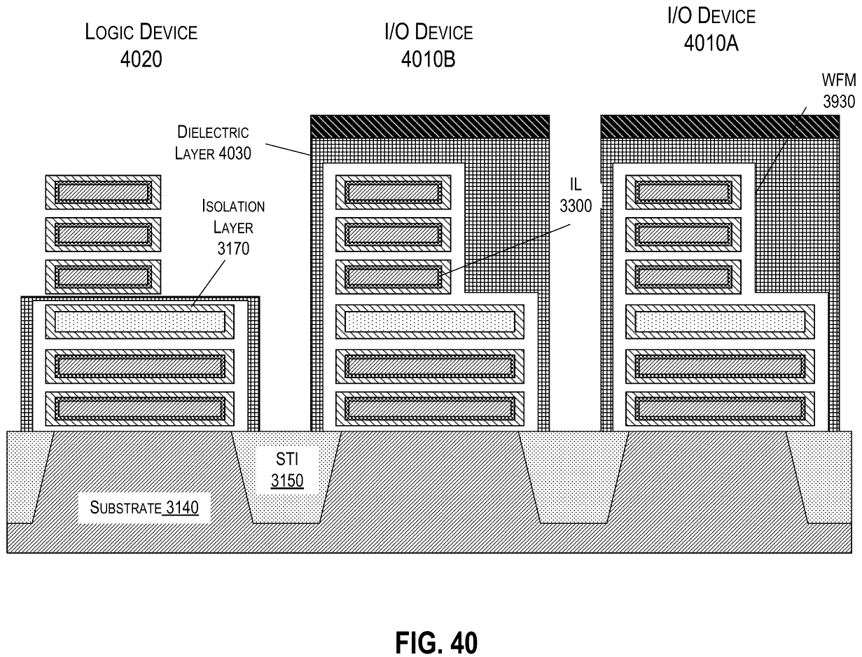

FIG. 40 illustrates a semiconductor device after the formation of the dielectric layer, in accordance with some embodiments. In some embodiments, a dielectric layer 4030 is formed over the semiconductor device in the logic device 4020, the I/O device 4010A, and the I/O device 4010B. Portions of the dielectric layer 4030 are removed from the logic device 4020. Subsequently, portions of WFM are removed from the logic device 4020.

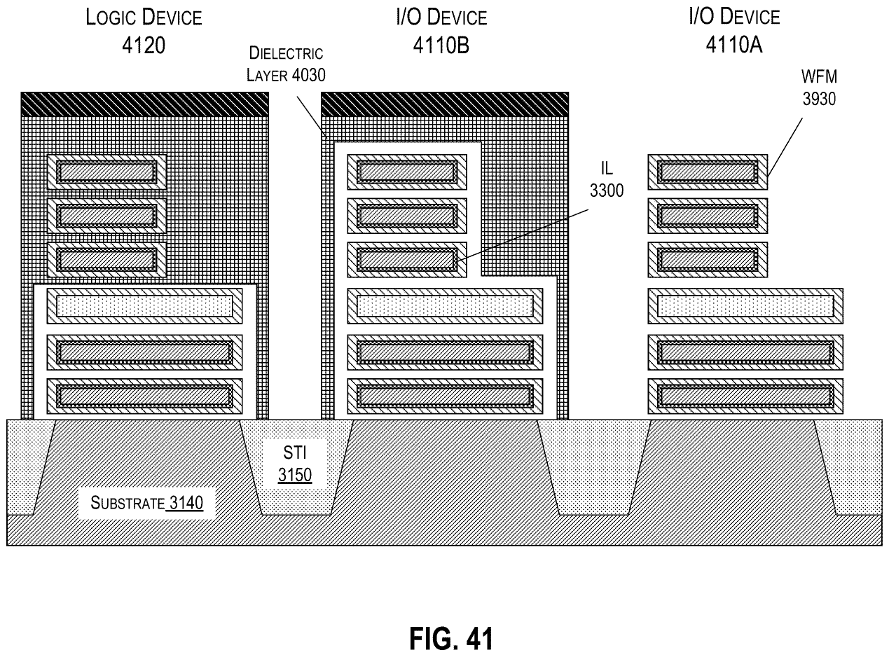

FIG. 41 illustrates a semiconductor device after the partial stripping the dielectric layer, in accordance with some embodiments. In some embodiments, portions of the dielectric layer are removed from one of the I/O devices, e.g., I/O device 4110B, and not the I/O device 4110A and the logic device 4120. Further, portions of WFM are removed from the I/O device 4110B. As such, I/O device 4110B does not include the WFM.

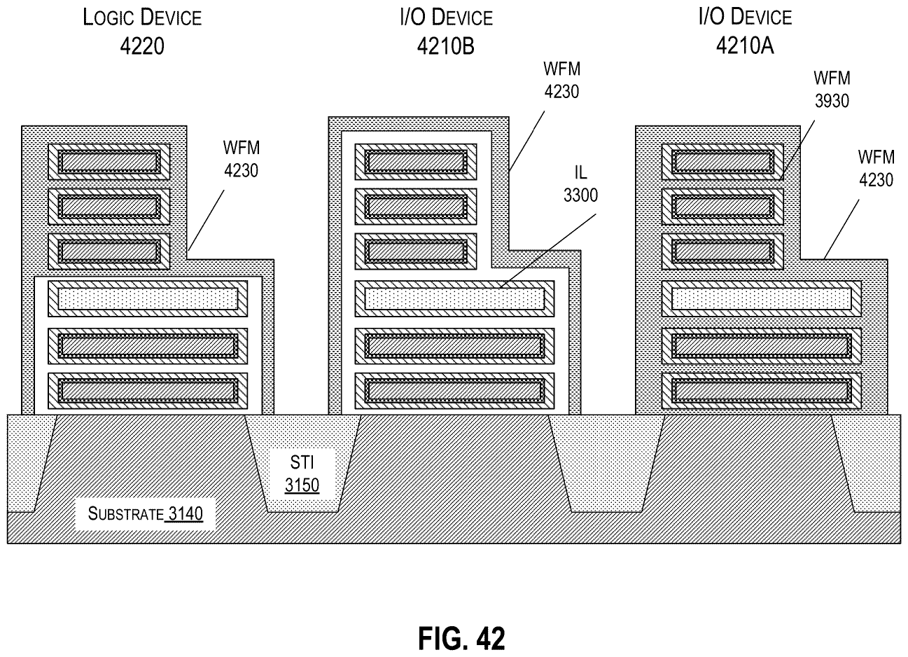

FIG. 42 illustrates a semiconductor device after the stripping the dielectric layer, in accordance with some embodiments. In some embodiments, the remaining dielectric layer is removed and an additional WFM, WFM 4230, is formed over the semiconductor device. As a result, the I/O device 4210A includes WFM 4230 and WFM 3930. The lower portions of the logic device 4220 includes the WFM 4230 and WFM 3930, and the upper portions of the logic device 4220 includes WFM 4230. I/O device 4210B includes WFM 4230 and does not include WFM 3930.

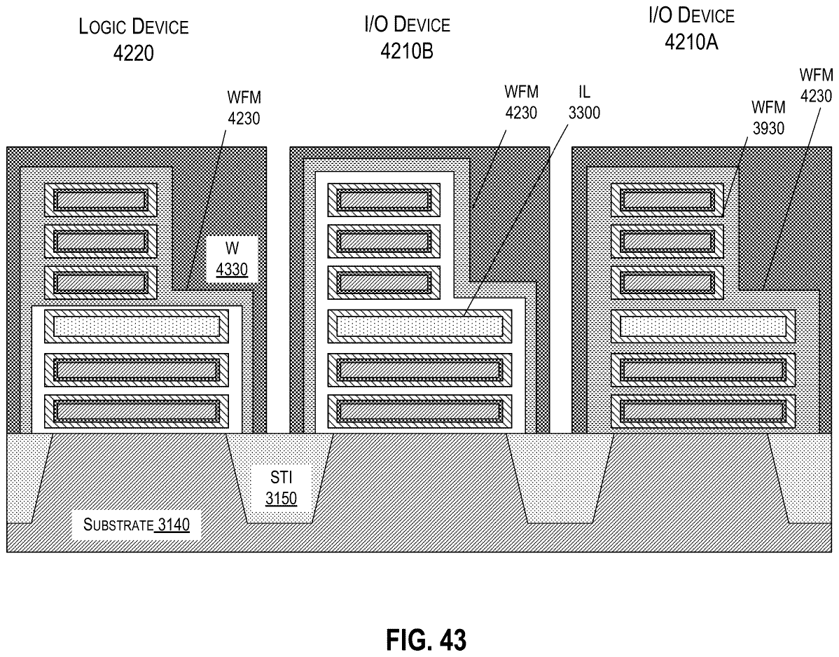

FIG. 43 illustrates a semiconductor device after the formation of a tungsten (W) layer, in accordance with some embodiments. In some embodiments, a W layer 4330 is formed over the semiconductor device.

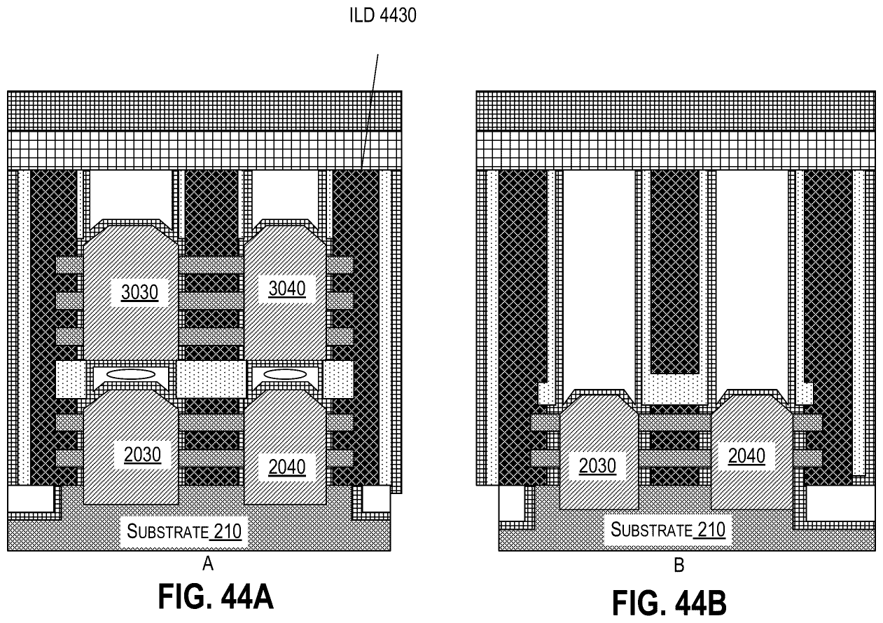

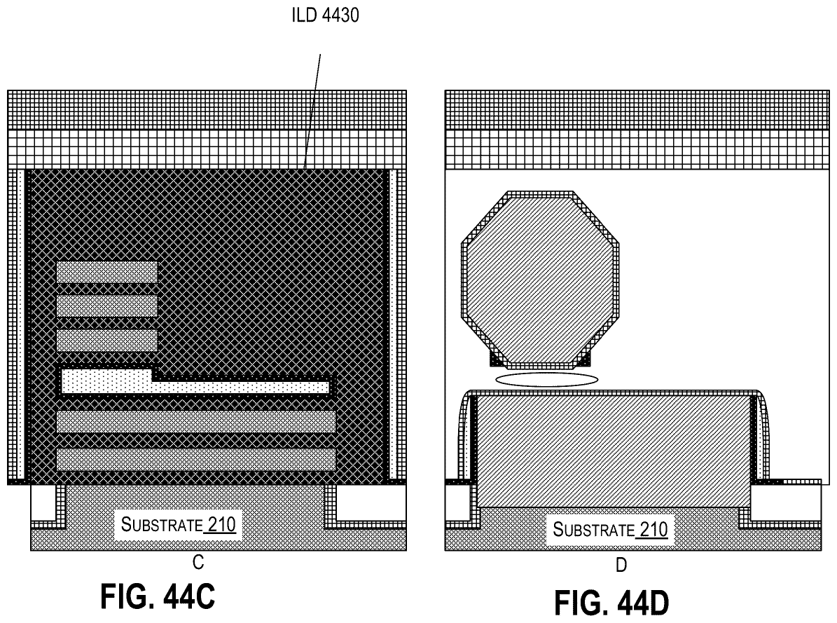

FIGS. 44-53 illustrate acts of manufacturing a semiconductor device, in accordance with some embodiments. To that end, FIGS. 44A-44D illustrate a semiconductor device after the formation of an interlayer dielectric. In some embodiments, an interlayer dielectric, ILD 4430 is formed over semiconductor device.

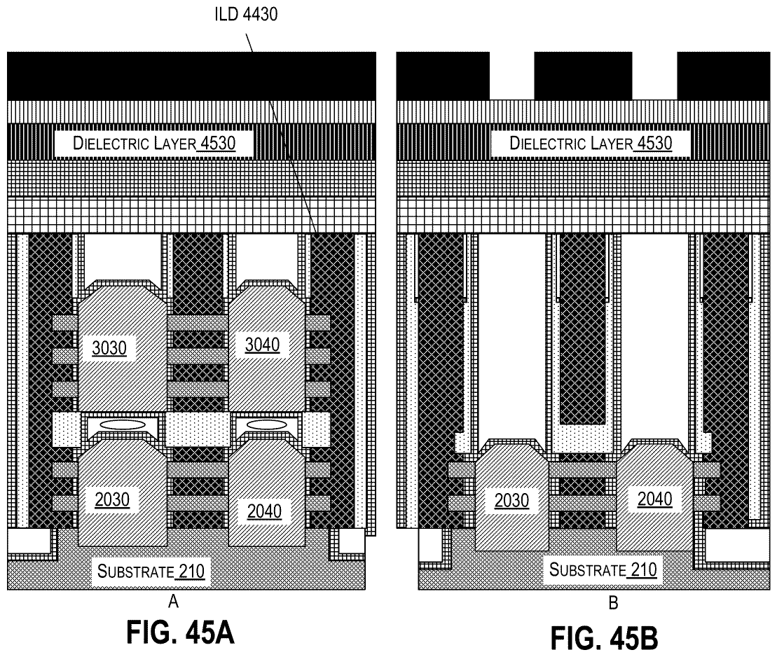

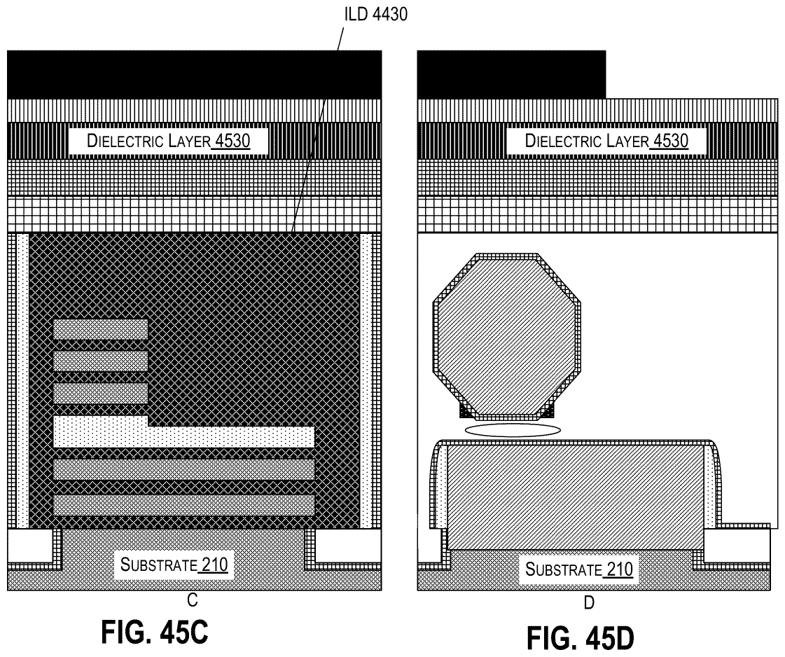

FIGS. 45A-45D illustrate a semiconductor device after the formation of a dielectric layer, according to some embodiments. In some embodiments, a dielectric layer 4530 is formed over the semiconductor device, followed by a lithography process to pattern the dielectric layer 4530.

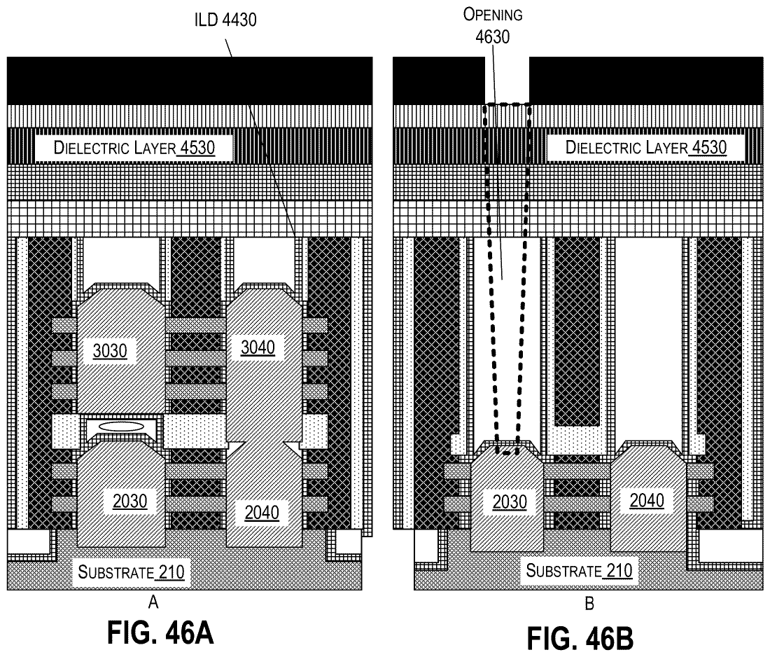

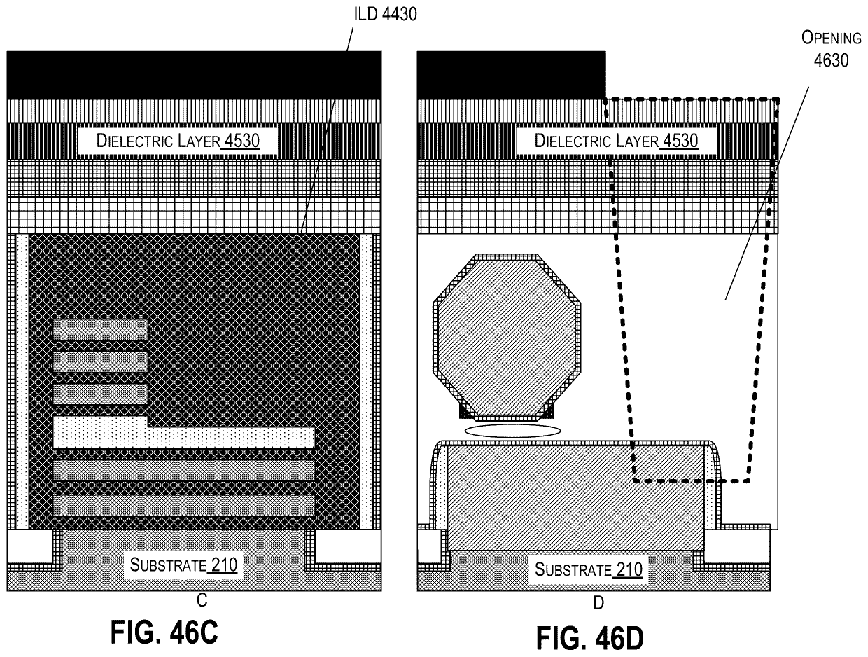

FIGS. 46A-46D illustrate a semiconductor device after the patterning of the semiconductor device, according to some embodiments. In some embodiments, portions of the semiconductor device are removed, e.g., by RIE, to form an opening 4630 for a bottom drain contact.

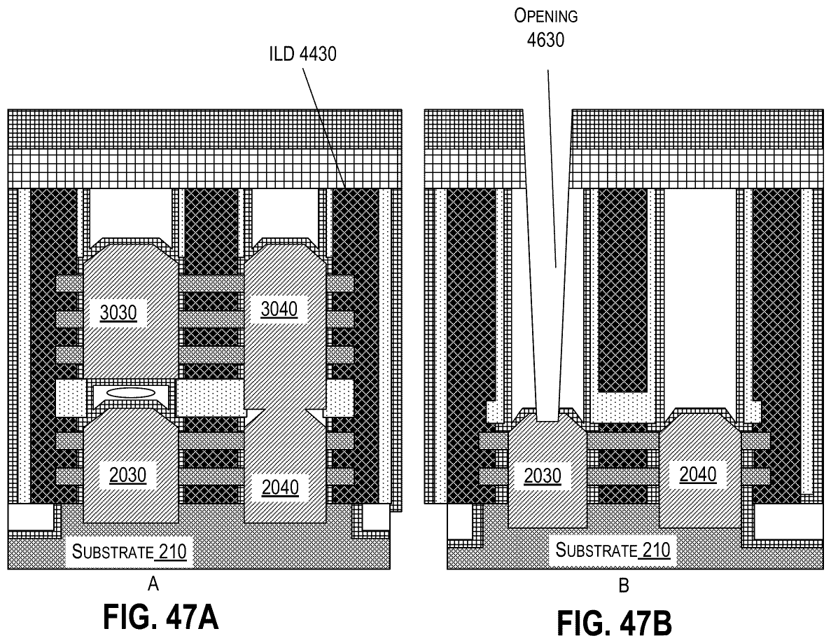

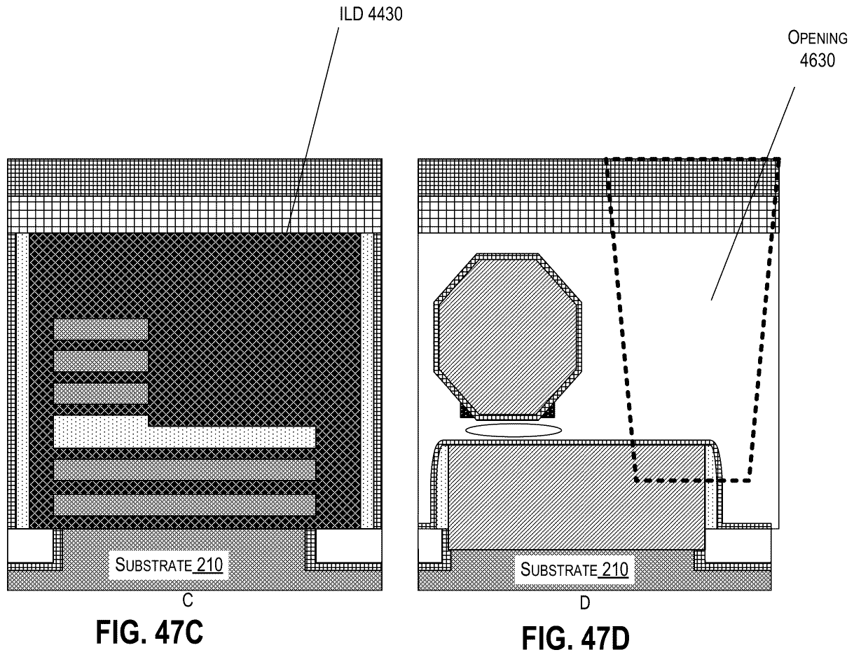

FIGS. 47A-47D illustrate a semiconductor device after the wet stripping, according to some embodiments. In some embodiments, a wet stripping process is performed to remove the dielectric layer.

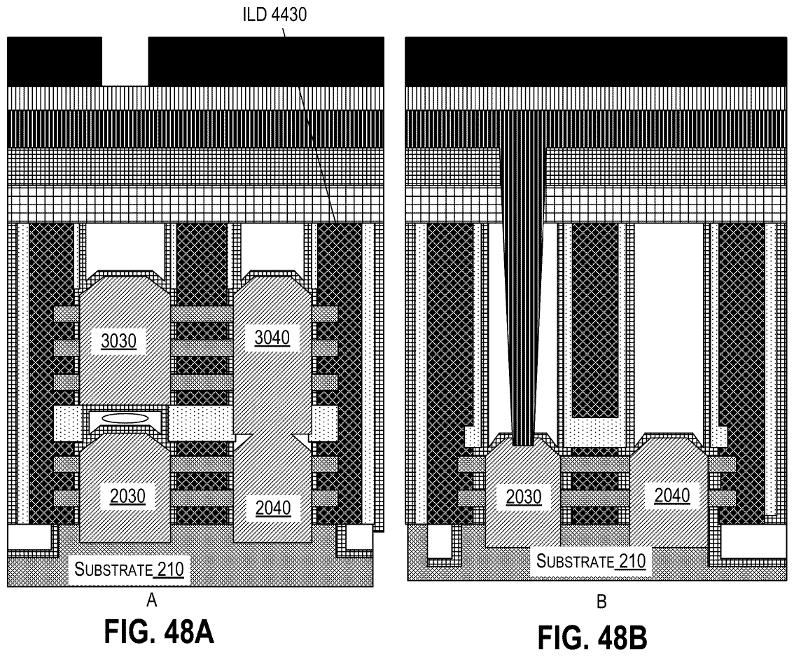

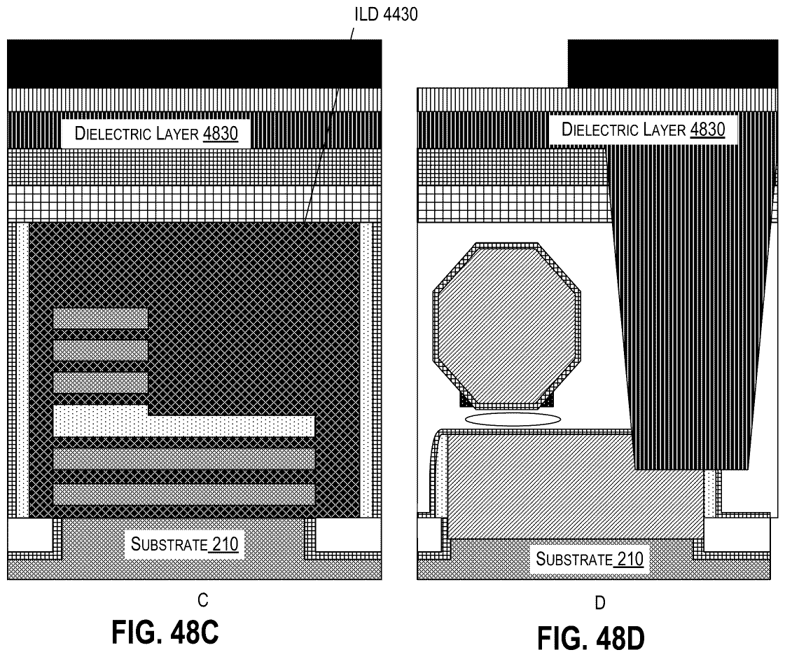

FIGS. 48A-48D illustrate a semiconductor device after the formation of a dielectric layer to pattern a contact, according to some embodiments. In some embodiments, an additional dielectric layer 4830 is formed and the opening is filled to pattern a top contact.

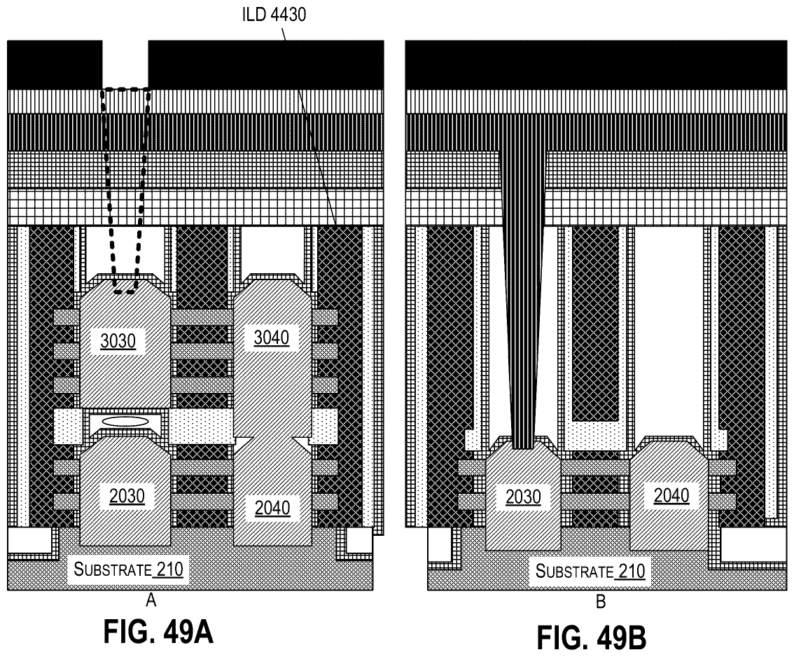

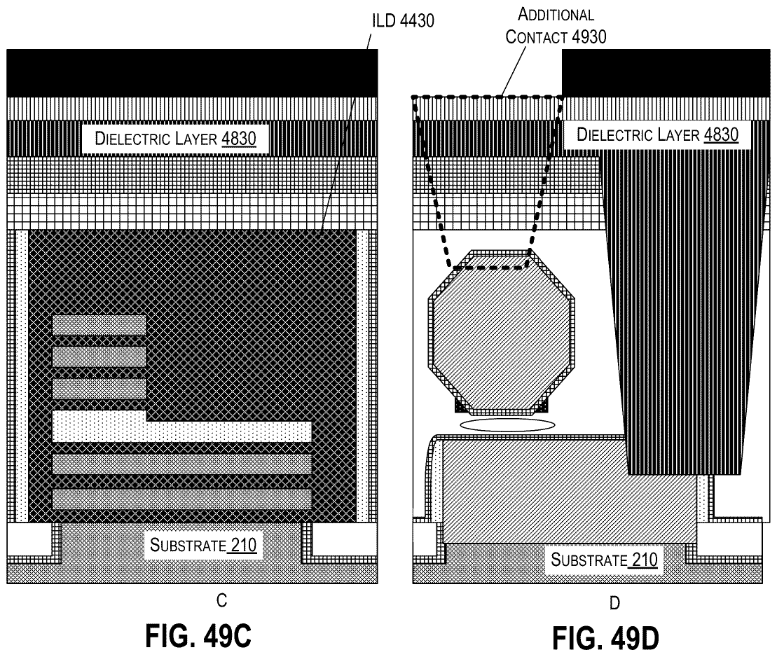

FIGS. 49A-49D illustrate a semiconductor device after the patterning of additional contact, according to some embodiments. In some embodiments, an additional contact 4930 is patterned over one of the FETs. It should be noted that, the top FET and bottom FET are connected to each other and do not need a contact.

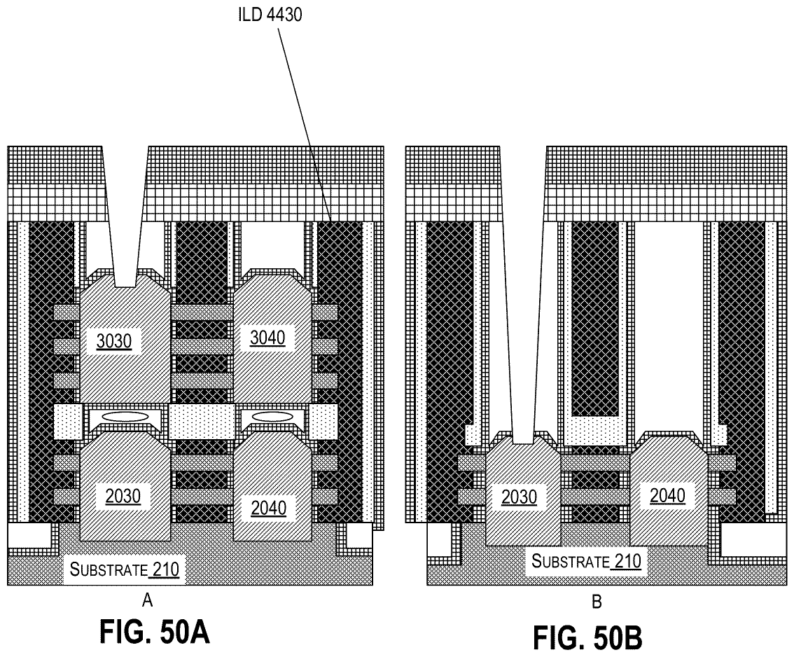

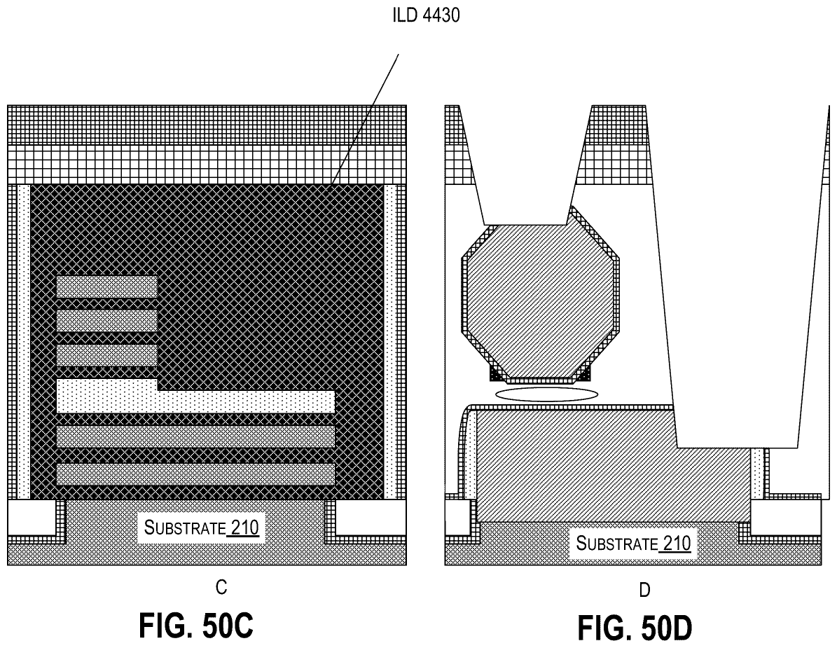

FIGS. 50A-50D illustrate a semiconductor device after the wet stripping, according to some embodiments. In some embodiments, a wet stripping is performed to remove the dielectric layer and the patterned contacts.

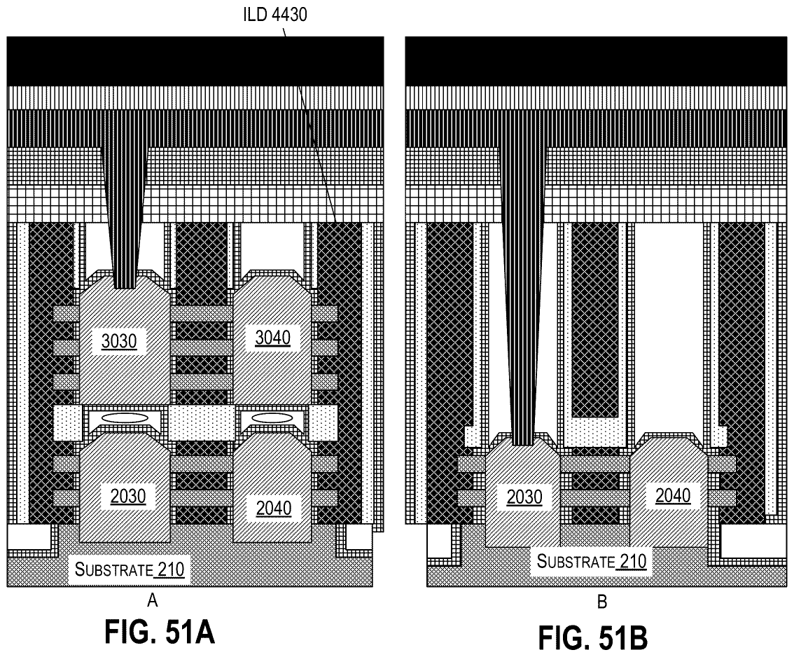

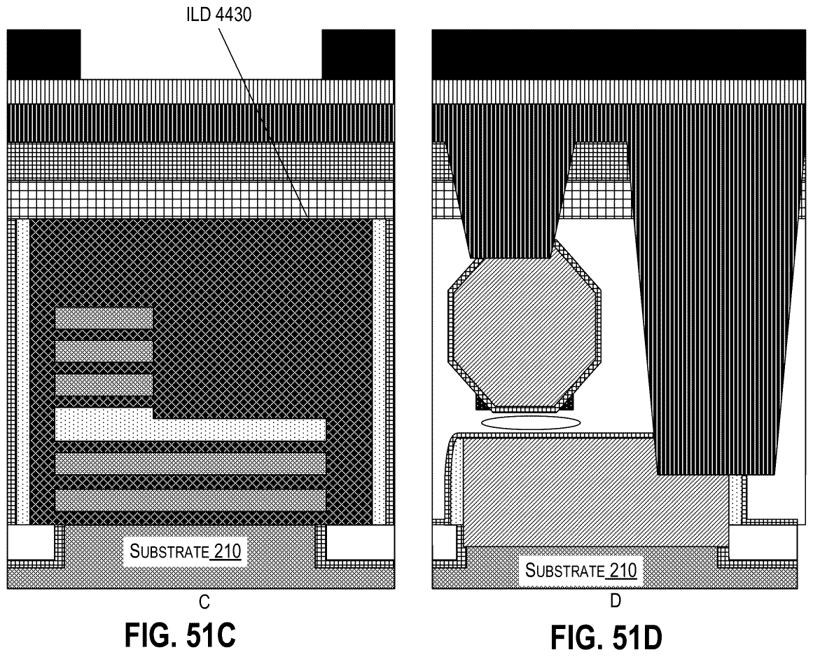

FIGS. 51A-51D illustrate a semiconductor device after the patterning of the gate contacts, according to some embodiments. In some embodiments, a lithography process is performed to pattern the gate contacts.

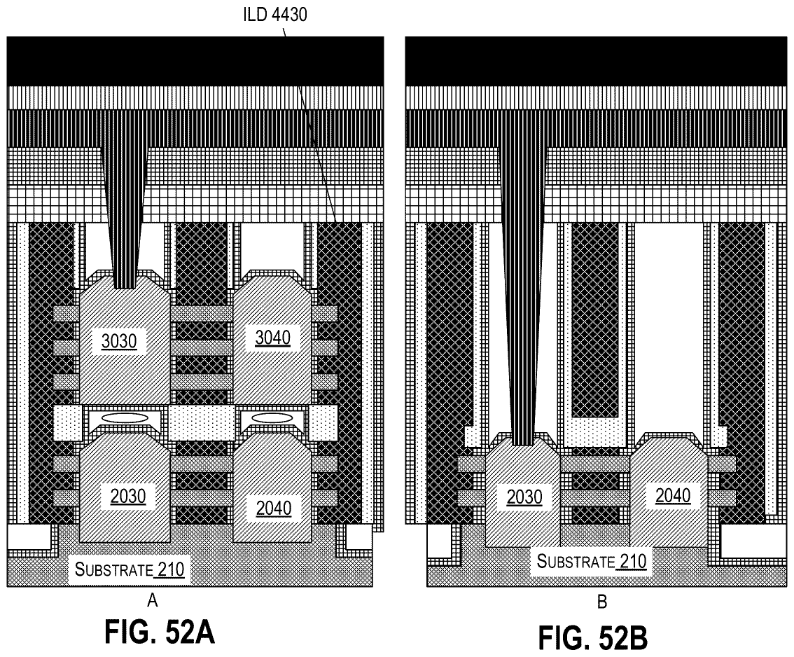

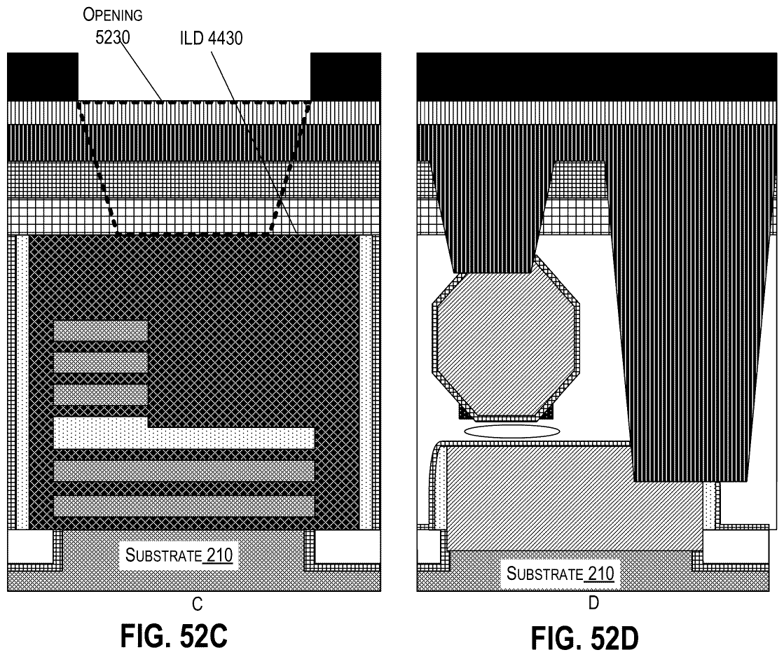

FIGS. 52A-52D illustrate a semiconductor device after the opening for the gate contacts, according to some embodiments. In some embodiments, portions of the semiconductor device over the gate regions are patterned to form an opening 5230 for the gate contacts.

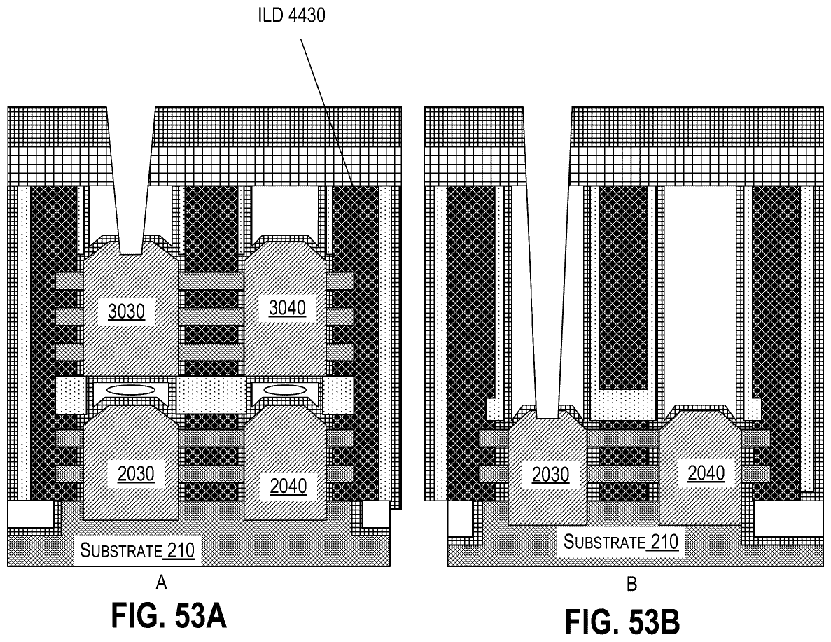

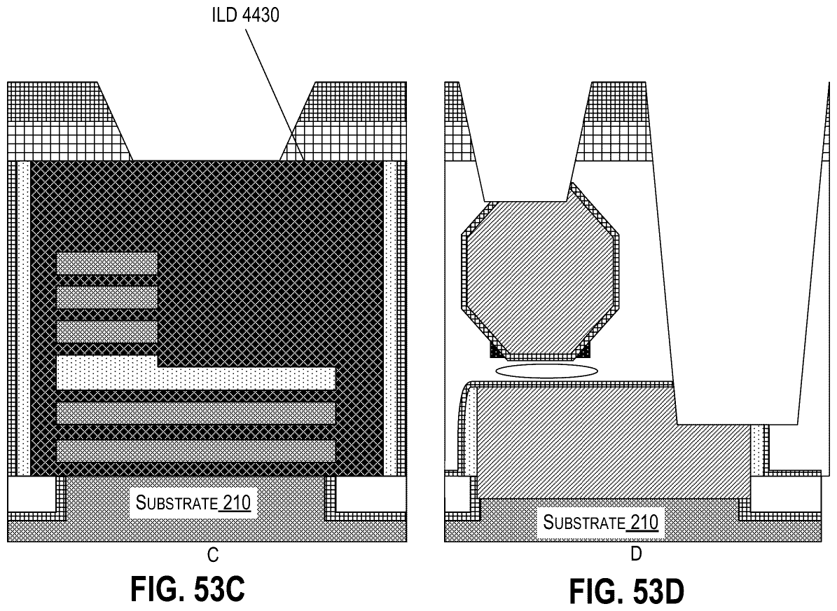

FIGS. 53A-53D illustrate a semiconductor device after the wet stripping, according to some embodiments. In some embodiments, a wet stripping is performed to remove the dielectric layer and all of the masks.

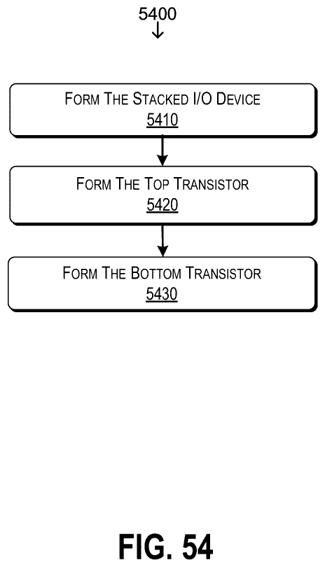

FIG. 54 illustrates a block diagram of a method 5400 for forming the semiconductor device, in accordance with some embodiments. As shown by block 5410, a stacked output/input device is formed.

As shown by block 5420, a top transistor is formed by forming a top source region and top drain region.

As shown by block 5430, a bottom transistor is formed by forming a bottom source region and a bottom drain region. The top source region is located over the bottom drain region, the top drain region is located over the bottom source region, the top source region is isolated from contact with the bottom drain region, and the top drain region is connected to the bottom source region.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
an input/output device comprising:
a top transistor comprising a top source region and top drain region; and
a bottom transistor comprising a bottom source region and a bottom drain region,
wherein:
the top source region is located over the bottom drain region,
the top drain region is located over the bottom source region,
the top source region is isolated from contact with the bottom drain region, and
the top drain region is connected to the bottom source region.

2. The semiconductor device of claim 1, wherein the top transistor and the bottom transistor are field-effect transistors.

3. The semiconductor device of claim 1, wherein the top transistor and the bottom transistor are doped with a P-type dopant.

4. The semiconductor device of claim 1, wherein the top transistor and the bottom transistor are doped with an N-type dopant.

5. The semiconductor device of claim 1, further comprising:
a top set of nanosheet gates horizontally extended between the top source region and the top drain region, and
a bottom set of nanosheet gates horizontally extended between the bottom source region and the bottom drain region.

6. The semiconductor device of claim 1, wherein the top drain region and the bottom source region are configured to serially connect the top transistor to the bottom transistor.

7. The semiconductor device of claim 1, further comprising a logic device connected to the input/output device.

8. A method of fabricating a semiconductor device, the method comprising:
forming a stacked input/output device comprising:
forming a top transistor by forming a top source region and top drain region; and
forming a bottom transistor by forming a bottom source region and a bottom drain region,
wherein:
the top source region is located over the bottom drain region,
the top drain region is located over the bottom source region,
the top source region is isolated from contact with the bottom drain region, and
the top drain region is connected to the bottom source region.

9. The method of claim 8, wherein the top transistor and the bottom transistor are field-effect transistors.

10. The method of claim 8, further comprising: doping the top transistor and the bottom transistor with a P-type dopant.

11. The method of claim 8, further comprising doping the top transistor and the bottom transistor with an N-type dopant.

12. The method of claim 8, further comprising:
forming a top set of nanosheet gates horizontally extended between the top source region and the top drain region, and
forming a bottom set of nanosheet gates horizontally extended between the bottom source region and the bottom drain region.

13. The method of claim 8, further comprising forming a serially connected top transistor and bottom transistor by connecting the top drain region and the bottom source region.

14. The method of claim 8, further comprising forming a logic device connected to the stacked input/output device.

15. A semiconductor device, comprising:
an input/output device comprising:
a top transistor comprising a top source region and top drain region; and
a bottom transistor comprising a bottom source region and a bottom drain region,
wherein the top transistor and the bottom transistor are doped with a same dopant.

16. The semiconductor device of claim 15, wherein:
the top source region is located over the bottom drain region,
the top drain region is located over the bottom source region,
the top source region is isolated from contact with the bottom drain region, and
the top drain region is connected to the bottom source region.

17. The semiconductor device of claim 15, wherein the top transistor and the bottom transistor are field-effect transistors.

18. The semiconductor device of claim 15, wherein the dopant is a P-type dopant or an N-type dopant.

19. The semiconductor device of claim 15, further comprising:
a top set of nanosheet gates horizontally extended between the top source region and the top drain region, and
a bottom set of nanosheet gates horizontally extended between the bottom source region and the bottom drain region.

20. The semiconductor device of claim 15, further comprising a logic device connected to the input/output device, and wherein the top drain region and the bottom source region are configured to serially connect the top transistor to the bottom transistor.
